(19) United States
(12) Patent Application Publication
(10) Pub. No.: US 2017/0090228 A1
(43) Pub. Date: Mar. 30, 2017

(54) DISPLAY DEVICE AND MANUFACTURING METHOD THEREOF

(71) Applicant: Japan Display Inc., Minato-ku (JP)

(72) Inventors: Tomokazu ISHIKAWA, Tokyo (JP); Masahiko NAKAMURA, Tokyo (JP); Masayuki MURAKAMI, Tokyo (JP); Koji KITAMURA, Tokyo (JP); Daisuke ITO, Tokyo (JP)

(73) Assignee: Japan Display Inc., Minato-ku (JP)

(21) Appl. No.: 15/270,531

(22) Filed: Sep. 20, 2016

(30) Foreign Application Priority Data
Sep. 28, 2015 (JP) 2015-190494

(51) Int. Cl. G02F 1/1339; G02F 1/1362; H01L 27/12; G02F 1/1368; H01L 23/544

(52) U.S. Cl. CPC G02F 1/1339; G02F 1/1368; H01L 23/544; H01L 27/1218; H01L 27/124; G02F 1/136286; G02F 2001/133354

(57) ABSTRACT

A display device includes a substrate and a seal. The seal is provided in a first frame region and a second frame region when seen in a plan view. A spacer is formed from a first end of the substrate to a second end of the substrate on the opposite side of the first end at a boundary between the first frame region and the second frame region. Further, the spacer is in contact with the seal on the first frame region side and on the second frame region side.

### CROSS-REFERENCE TO RELATED APPLICATION

The present application claims priority from Japanese Patent Application No. 2015-190494 filed on Sep. 28, 2015, the content of which is hereby incorporated by reference into this application.

### TECHNICAL FIELD OF THE INVENTION

The present invention relates to a display device and a manufacturing method thereof and for example, relates to a technique which is effectively applied to a display device that includes a frame region provided outside a display region and a manufacturing method thereof.

### BACKGROUND OF THE INVENTION

For example, a display device such as a liquid crystal display device includes a display region and a frame region outside the display region. In addition, such a display device includes an array substrate and a counter substrate arranged to face the array substrate. The array substrate is provided with a plurality of pixels in the display region. The plurality of pixels are arranged in a matrix, for example. A seal is provided between the array substrate and the counter substrate in the frame region. The seal allows the array substrate and the counter substrate to adhere to each other. In addition, a spacer is provided in the array substrate or the counter substrate. The spacer keeps an interval between the array substrate and the counter substrate.

For example, Japanese Patent Application Laid-Open Publication No. 2014-52546 (Patent Document 1) describes a technique in which a display panel is provided with an array substrate, a counter substrate arranged to face the array substrate with a gap, and a sealing member which faces a frame region surrounding the display region and bonds the array substrate and the counter substrate to each other.

### SUMMARY OF THE INVENTION

In such a display device, a semiconductor chip is provided in the frame region. A frame region in which the semiconductor chip is arranged is referred to as a lower frame region, and a frame region which is arranged on the opposite side of the lower frame region with the display region interposed therebetween is referred to as an upper frame region. In this case, the display device is designed by changing only a width of the upper frame region without changing each width of frame regions which are arranged on both sides in a direction crossing a direction in which the lower frame region is arranged with respect to the display region, that is, a left frame region and a right frame region, in some cases.

In this case, for example, in order to manufacture two types of display devices having different widths of upper frame regions, it is necessary to separately prepare a set of a plurality of photomasks used for photolithography in processes of manufacturing the display devices, respectively. Thus, there is a risk that costs required for the manufacture of the display devices increase or a period required for the manufacture of the display devices increases, and thus, it is difficult to easily manufacture the two types of display devices having different widths of upper frame regions.

The present invention has been made in order to solve the above-described problem of the related art, and an object thereof is to provide a display device which is capable of easily manufacturing two types of display devices having different widths of upper frame regions.

The typical ones of the inventions disclosed in the present application will be briefly described as follows.

A display device as an aspect of the present invention includes a first substrate, a second substrate arranged to face the first substrate, and a seal provided between the first substrate and the second substrate and allowing the first substrate and the second substrate to adhere to each other. The first substrate includes a first region, and a second region which is arranged on a first side in a first direction with respect to the first region when seen in a plan view. A plurality of pixels are arranged in the first region. The seal is provided in a first part and a second part in the second region when seen in a plan view, the first part is arranged on the first region side with respect to a spacer, and the second part is arranged on an opposite side of the first region with the spacer interposed therebetween. The spacer is formed from a first end to a second end of the second substrate at a boundary between the first part and the second part, and the spacer is in contact with the seal on the first part side and the second part side of the spacer.

In addition, as another aspect of the present invention, the display device may include a first alignment mark provided in the first substrate or the second substrate, and the first alignment mark may be superimposed on the spacer in the first direction.

In addition, as another aspect of the present invention, the first alignment mark may be provided in the first part at the boundary between the first part and the second part, and a second alignment mark may be provided in a third end of the first substrate or the second substrate in the second part.

In addition, as another aspect of the present invention, the display device may include a plurality of scanning lines and a plurality of signal lines provided in the first substrate. Also, a pattern provided on a same layer as the plurality of scanning lines or the plurality of signal lines may be arranged in the second part when seen in a plan view, and the pattern may be floating.

In addition, as another aspect of the present invention, a third end of the first substrate and a fourth end of the second substrate in the second part may be exposed from the seal.

In addition, as another aspect of the present invention, the second alignment mark may have a shape different from a shape of the first alignment mark when seen in a plan view.

In addition, as another aspect of the present invention, the spacer may be a plurality of island-like spacers interspersed in an extension direction of a plurality of scanning lines.

Alternatively, a method of manufacturing a display device as an aspect of the present invention includes the steps of (a) providing a plurality of pixels, respectively, in a plurality of substrate formation regions of a first motherboard, (b) providing a spacer, a first alignment mark, and a second alignment mark, respectively, in a plurality of substrate formation regions of a second motherboard, (c) bonding the first motherboard and the second motherboard to each other via a seal, and (d) determining whether the substrate formation region is scribed by a first size or a second size larger than the first size. In addition, the method of manufacturing a display device includes the step of (e) dividing the first motherboard and the second motherboard into a plurality of display panels through the scribing.

In addition, as another aspect of the present invention, vicinity of the first alignment mark may be cut in scribing by the first size, and vicinity of the second alignment mark spaced apart from the plurality of pixels farther than the first alignment mark may be cut in scribing by the second size.

In addition, as another aspect of the present invention, the scribing may be performed along the spacer inscribing by the first size.

### BRIEF DESCRIPTIONS OF THE DRAWINGS

FIG. 1 is a plan view illustrating an example of a display device according to an embodiment;

FIG. 2 is a cross-sectional view illustrating an example of the display device according to the embodiment;

FIG. 3 is a cross-sectional view illustrating an example of the display device according to the embodiment;

FIG. 4 is an equivalent circuit of the display device according to the embodiment;

FIG. 5 is a plan view of the display device according to the embodiment;

FIG. 6 is a plan view of a frame region of the display device according to the embodiment;

FIG. 7 is a plan view of the frame region of the display device according to the embodiment;

FIG. 8 is a cross-sectional view of the frame region of the display device according to the embodiment;

FIG. 9 is a cross-sectional view of the frame region of the display device according to the embodiment;

FIG. 10 is a plan view of the display device during a manufacturing process according to the embodiment;

FIG. 11 is a plan view of the display device during the manufacturing process according to the embodiment;

FIG. 12 is a plan view of the display device during the manufacturing process according to the embodiment;

FIG. 13 is a cross-sectional view of the display device during the manufacturing process according to the embodiment;

FIG. 14 is a plan view of the display device during the manufacturing process according to the embodiment;

FIG. 15 is a plan view of a frame region of a display device according to a modification example of the embodiment; and

FIG. 16 is a plan view of the display device during a manufacturing process according to the modification example of the embodiment.

### DESCRIPTIONS OF THE PREFERRED EMBODIMENTS

An embodiment of the present invention will be described below with reference to the drawings.

Note that this disclosure is an example only and suitable modifications which can be easily conceived by those skilled in the art without departing from the gist of the present invention are included within the scope of the present invention as a matter of course. In addition, in order to further clarify the description, a width, a thickness, a shape, and the like of respective portions may be schematically illustrated in the drawings as compared to aspects of the embodiments, but they are examples only and do not limit the interpretation of the present invention.

In addition, in this specification and the respective drawings, the same components described in the drawings which have been described before are denoted by the same reference characters, and detailed description thereof may be omitted as needed.

In addition, in some drawings used in the embodiments, hatching may be omitted even in a cross-sectional view so as to make the drawings easy to see. Also, hatching may be used even in a plan view so as to make the drawings easy to see.

A technique to be described in the following embodiment can be widely applied to a display device provided with a mechanism that supplies a signal from a periphery of a display region to a plurality of elements provided in the display region including a display function layer. Examples of such a display device include various display devices, for example, a liquid crystal display device, an organic electro-luminescence (EL) display device, and the like. In the following embodiment, the liquid crystal display device will be described as a representative example of the display device.

In addition, a display device of a horizontal electric field mode will be described by way of example in the embodiment described below, but the present invention is not limited thereto.

### Embodiment

<Configuration of Display Device>

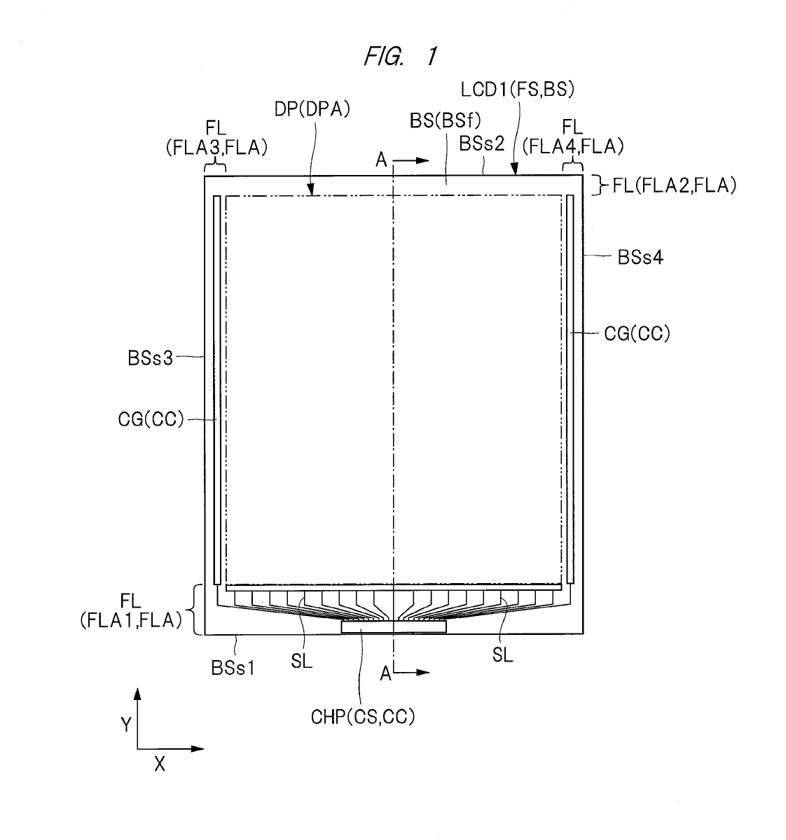

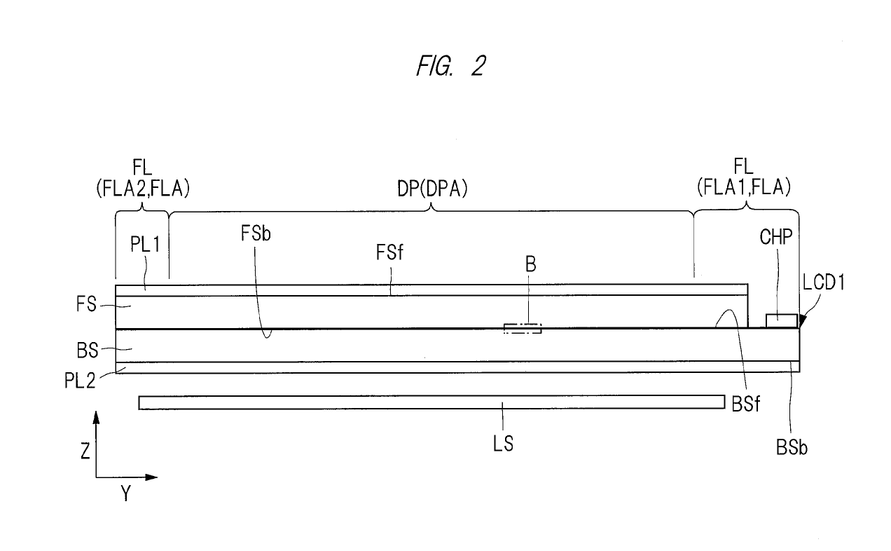

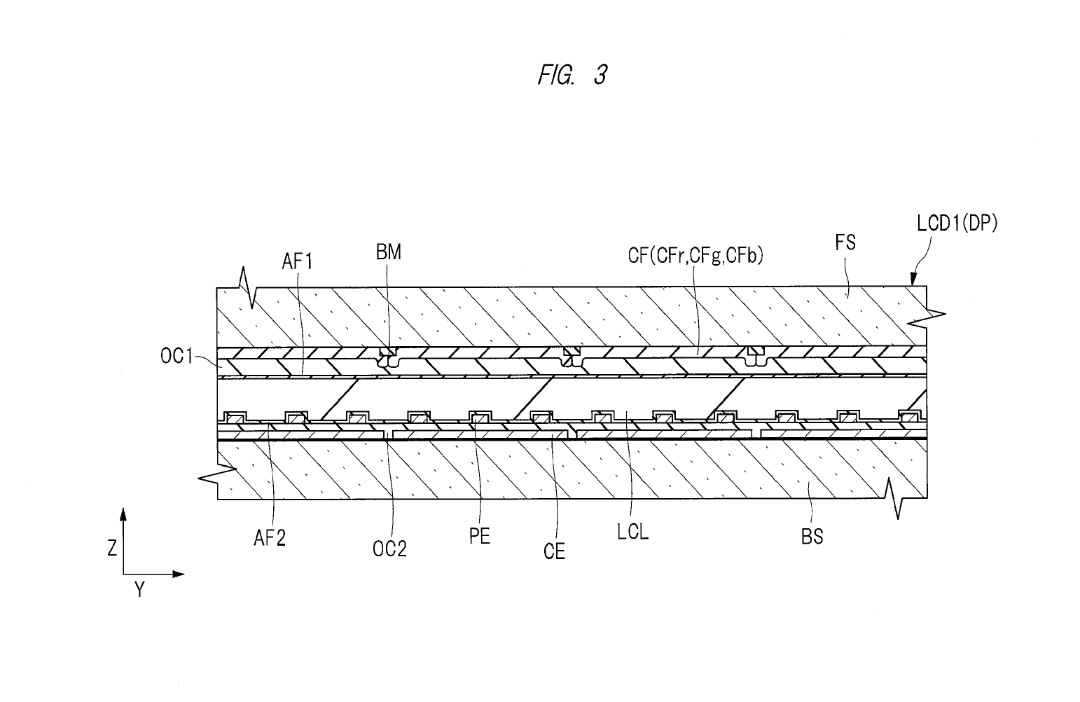

First, referring to FIGS. 1 to 3, a configuration of a display device will be described. FIG. 1 is a plan view illustrating an example of the display device according to the embodiment. FIGS. 2 and 3 are cross-sectional views illustrating an example of the display device according to the embodiment. FIG. 2 is a cross-sectional view taken along a line A-A of FIG. 1. In addition, FIG. 3 is an enlarged cross-sectional view of a section B of FIG. 2.

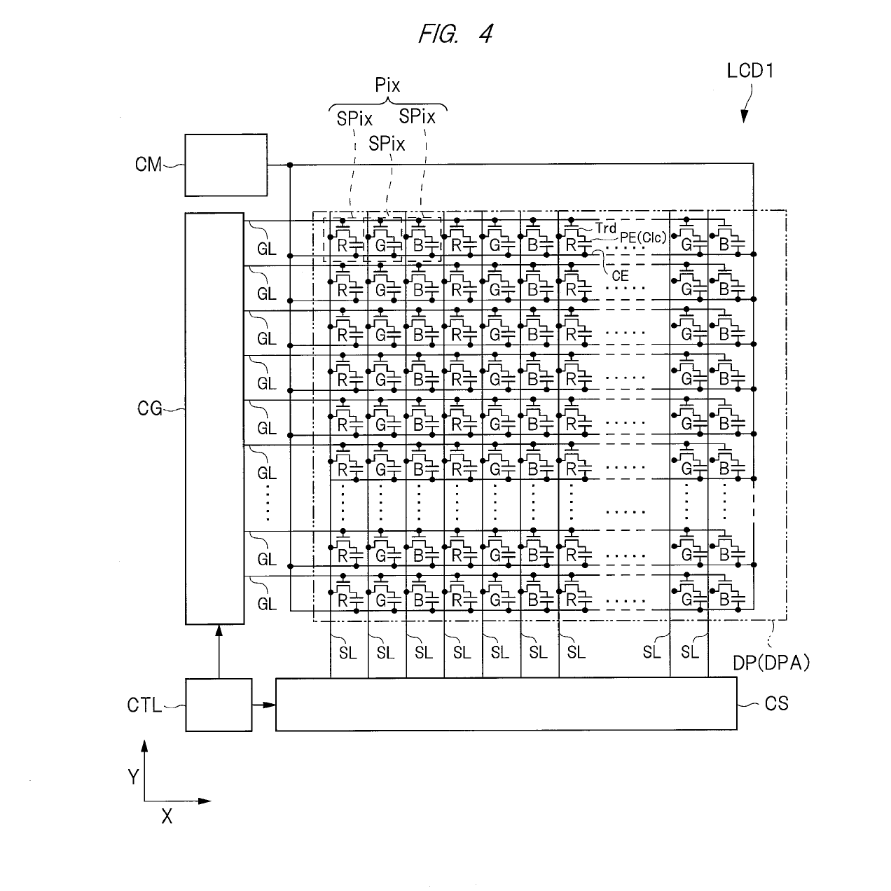

Note that FIG. 1 does not illustrate a scanning line (scanning signal line) GL (see FIG. 4 to be described later) and a signal line (video signal line) SL (see FIG. 4 to be described later) in a display region DPA for viewability. In addition, FIG. 2 is a cross section but does not illustrate hatching for viewability.

As illustrated in FIG. 1, the display device LCD1 according to the present embodiment includes a display section DP that displays an image. The display device LCD1 includes a substrate BS, referred to also as an array substrate, and a substrate FS, referred to also as counter substrate, and the display region DPA is a region of the substrate BS in which the display section DP is provided, for example. In addition, the display device LCD1 includes a frame section (peripheral section) FL which is a part around the display section DP when seen in a plan view and does not display the image. A region in which the frame section FL is provided is a frame region FLA. That is, the frame region FLA is a region (peripheral region) outside the display region DPA.

Note that, in the specification of the present application, the expression “when seen in a plan view” means the case of viewing from a direction vertical to a counter surface BSf (see FIG. 2) which serves as a main surface of the substrate BS as illustrated in FIG. 1. In addition, two directions which cross, and preferably, are orthogonal to each other on the counter surface BSf serving as the main surface of the substrate BS are set to an X-axis direction and a Y-axis direction, and a direction vertical to the counter surface BSf serving as the main surface of the substrate BS is set to a Z-axis direction (see FIG. 2).

In addition, the display device LCD1 has a structure in which a liquid crystal layer serving as a display function layer is formed between a pair of substrates arranged to face each other. That is, as illustrated in FIG. 2, the display device LCD1 includes a substrate (counter substrate) FS on a display surface side, the substrate (array substrate) BS positioned on the opposite side of the substrate FS, and a liquid crystal layer LCL (see FIG. 3) arranged between the substrate FS and the substrate BS.

In addition, the substrate BS illustrated in FIG. 1 includes a side BSs1 extending along the X-axis direction, a side BSs2 extending along the X-axis direction to be parallel with the side BSs1, a side BSs3 extending along the Y-axis direction which crosses, and is preferably orthogonal to the X-axis direction, and a side BSs4 extending along the Y-axis direction to be parallel with the side BSs3 when seen in a plan view. Each distance from the side BSs2, the side BSs3, and the side BSs4 which are included in the substrate BS illustrated in FIG. 1 to the display section DP is substantially the same and is shorter than a distance from the side BSs1 to the display section DP.

Hereinafter, the case of describing a “peripheral edge portion of the substrate BS” means any of the side BSs1, the side BSs2, the side BSs3, and the side BSs4 forming an outer edge of the substrate BS in the specification of the present application. In addition, the case of simply describing the “peripheral edge portion” means a peripheral edge portion of the substrate BS.

The display section DP includes a plurality of pixels Pix (see FIG. 4 to be described later) serving as display elements. That is, the plurality of pixels Pix are provided in the display region DPA of the substrate BS. The plurality of pixels Pix are arrayed in a matrix in the X-axis direction and the Y-axis direction. In the embodiment, each of the plurality of pixels Pix includes a thin-film transistor (TFT) which is formed in the display region DPA of the substrate BS on the counter surface BSf side.

The display device LCD1 includes a plurality of scanning lines GL and a plurality of signal lines SL as will be described later with reference to FIG. 4. Each of the plurality of scanning lines GL is electrically connected to the plurality of pixels Pix arrayed in the X-axis direction, and each of the plurality of signal lines SL is electrically connected to the plurality of pixels Pix arrayed in the Y-axis direction as will be described later with reference to FIG. 4.

In addition, the display device LCD1 includes a drive circuit CC. The drive circuit CC includes a scanning line drive circuit CG and a video line drive circuit CS. The scanning line drive circuit CG is electrically connected to the plurality of pixels Pix (see FIG. 4 to be described later) via the plurality of scanning lines GL (see FIG. 4 to be described later), and the video line drive circuit CS is electrically connected to the plurality of pixels Pix (see FIG. 4 to be described later) via the plurality of signal lines SL.

In the example illustrated in FIG. 1, the frame region FLA includes frame regions FLA1, FLA2, FLA3, and FLA4. The frame region FLA1 is a region which is arranged on one side (lower side in FIG. 1) in the Y-axis direction with respect to the display region DPA when seen in a plan view and is a region in which a semiconductor chip CHP is arranged. The frame region FLA2 is a region which is arranged on the opposite side (upper side in FIG. 1) of the frame region FLA1 with the display region DPA interposed therebetween. The frame region FLA3 is a region which is arranged on one side (left side in FIG. 1) in the X-axis direction with respect to the display region DPA when seen in a plan view, and the frame region FLA4 is a region which is arranged on the opposite side of the frame region FLA3 with the display region DPA interposed therebetween.

In the example illustrated in FIG. 1, the semiconductor chip CHP is provided on the substrate BS. The semiconductor chip CHP is arranged in the frame region FLA1 when seen in a plan view. The video line drive circuit CS is provided in the semiconductor chip CHP. Accordingly, the video line drive circuit CS is provided inside the frame region FLA1 which is a region on the counter surface BSf side of the substrate BS and the region arranged on one side in the Y-axis direction with respect to the display region DPA.

Note that the frame region FLA1 in which the semiconductor chip CHP is arranged will be referred to as a lower frame region and the frame region FLA2 arranged on the opposite side of the frame region FLA1 with the display region DPA interposed therebetween will be referred to as an upper frame region, in some cases. In this case, the frame regions FLA3 and FLA4 which are arranged on both sides in the direction (X-axis direction) crossing the direction (Y-axis direction) in which the frame region FLA1 is arranged with respect to the display region DPA will be referred to as a left frame region and a right frame region, respectively, in some cases.

In addition, the semiconductor chip CHP may be provided in the frame region FLA1 through use of a so-called chip on glass (COG) technique or may be provided outside the substrate BS and connected to the substrate BS via flexible printed circuits (FPC). A terminal portion that connects the substrate BS with the outside is provided in the frame region FLA1.

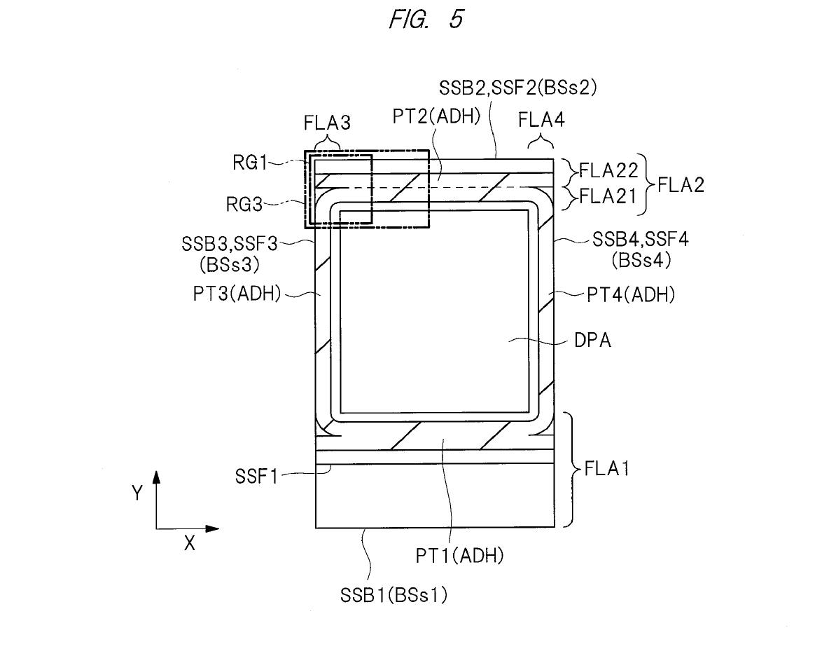

Note that the display device LCD1 includes a seal ADH which is arranged in the frame region FLA when seen in a plan view, as will be described later with reference to FIGS. 5 to 9. The seal ADH is formed so as to continuously surround the periphery of the display section DP, and the substrate FS and the substrate BS illustrated in FIG. 2 are adhesively fixed to each other via a sealing member provided in the seal ADH. In this manner, it is possible to seal the liquid crystal layer LCL (see FIG. 3) serving as the display function layer by providing the seal ADH around the display section DP.

In addition, a backlight LS which is composed of an optical element such as a light source and a diffusion plate, and a polarizing plate PL2 which polarizes light generated from the backlight LS are provided on a back surface BSb side of the substrate BS of the display device LCD1 as illustrated in FIG. 2. The polarizing plate PL2 is fixed to the substrate BS. Meanwhile, a polarizing plate PL1 is provided on a back surface FSf side of the substrate FS. The polarizing plate PL1 is fixed to the substrate FS.

Note that FIG. 2 illustrates basic component parts of the display device and other parts such as a touch panel and a protection layer can be added to the component parts illustrated in FIG. 2 as a modification example.

In addition, the display device LCD1 includes a plurality of pixel electrodes PE and common electrodes CE which are arranged between the substrate FS and the substrate BS as illustrated in FIG.

3. As described above, the display device LCD1 according to the present embodiment is the display device of the horizontal electric field mode, and thus, each of the plurality of pixel electrodes PE and common electrodes CE is formed in the substrate BS. The substrate B.S. is composed of a glass substrate or the like, and a circuit for image display is mainly formed therein. The substrate B.S. includes the counter surface BSf (see FIG. 2), positioned on the substrate FS side, and the back surface BSb (see FIG. 2) positioned on the opposite side thereof. A drive element such as a TFT and the plurality of pixel electrodes PE are formed in a matrix on the counter surface BSf side of the substrate B.S. In addition, the substrate B.S. includes the display region DPA and the frame region FLA provided outside the display region DPA. The substrate B.S. may be composed of resin such as polyimide other than the glass substrate.

The example of FIG. 3 illustrates the display device LCD1 of the horizontal electric field mode (particularly, the FFS mode), and thus, the common electrode CE is formed on the counter surface BSf side of the substrate B.S. (see FIG. 2) and is covered by an insulating layer OC2. In addition, the plurality of pixel electrodes PE are formed on the insulating layer OC2 on the substrate FS side so as to face the common electrode CE with the insulating layer OC2 interposed therebetween.

In addition, the substrate FS illustrated in FIG. 3 is composed of a glass substrate or the like, and a color filter CF which forms an image for color display is formed therein. The substrate FS includes the back surface FSf (see FIG. 2) on the display surface side and a counter surface FSb (see FIG. 2) which is positioned on the opposite side of the back surface FSf. The substrate FS is arranged to face the substrate B.S. in a state in which the counter surface BSf of the substrate B.S. and the counter surface FSb of the substrate FS face each other. Note that the substrate (the array substrate) B.S. can also be called a TFT substrate, and the substrate (counter substrate) FS in which the color filter CF is formed can also be called a color filter substrate. In addition, a configuration in which the color filter CF is provided in the substrate B.S. as the TFT substrate maybe employed as a modification example with respect to FIG. 3.

Color filter pixels CFr, CFg, and CFb of three colors including R (red), G (green), and B (blue) are periodically arrayed in the color filter CF of the substrate FS which is the counter substrate.

In addition, a light-shielding film BM is formed in each boundary among the color filter pixels CFr, CFg, and CFb of the respective colors. The light-shielding film BM is called a black matrix and is composed of a film that has a light-shielding property, for example, black resin, a metal having low reflectivity, or the like. The light-shielding film BM is formed in a lattice when seen in a plan view.

The light-shielding film BM is formed in any of the display region DPA and the frame region FLA. In general, of an opening portion which is formed in the light-shielding film BM and in which the color filter CF is buried, an end of the opening portion on the peripheral edge portion side is defined as a boundary between the display region DPA and the frame region FLA. Note that a dummy color filter may be provided on the peripheral edge portion side of the display region DPA. Further, the light-shielding film formed in the frame region FLA is provided from the display region DPA to an end of the substrate FS.

In addition, the substrate FS includes a resin layer OC1 that covers the color filter CF. Since the light-shielding film BM is formed in each boundary among the color filter pixels CFr, CFg, and CFb of the respective colors, the color filter CF has an irregular surface on the liquid crystal layer side. The resin layer OC1 functions as a planarization film that performs planarization of irregularities of the color filter CF on the liquid crystal layer side. Alternatively, the resin layer OC1 functions as a protection film that prevents impurities from being diffused from the color filter CF to the liquid crystal layer. The resin layer OC1 contains a component which is cured by receiving energy, for example, a thermosetting resin and a photocurable resin, so as to enable a resin material to be cured. The resin layer OC1 is also provided in the frame region FLA.

In addition, the liquid crystal layer LCL which forms a display image due to an electric field formed when a voltage for display is applied between the pixel electrode PE and the common electrode CE is provided between the substrate FS and the substrate B.S.

In addition, the substrate FS includes an alignment film AF1 which covers the resin layer OC1 on the counter surface FSb that is an interface in contact with the liquid crystal layer LCL. In addition, the substrate B.S. includes an alignment film AF2 which covers the insulating layer OC2 and the plurality of pixel electrodes PE on the counter surface BSf that is an interface in contact with the liquid crystal layer LCL. The alignment films AF1 and AF2 are resin films which are formed to arrange an initial alignment of liquid crystals included in the liquid crystal layer LCL and are made of, for example, polyimide resin. The alignment films AF1 and AF2 are also provided in the frame region FLA and may be provided to the end of the substrate FS.

Light emitted from the backlight LS (see FIG. 2) is subjected to filtering by the polarizing plate PL2 (see FIG. 2) and is incident to the liquid crystal layer LCL in the display device LCD1 illustrated in FIG. 3. A polarization state of the light incident to the liquid crystal layer LCL is changed by the liquid crystals, and then, the light is emitted from the substrate FS.

In this case, the alignment of liquid crystals is controlled by the electric field which is formed when the voltage is applied to the pixel electrode PE and the common electrode CE, and the liquid crystal layer LCL functions as an optical shutter.

Note that a thickness of the liquid crystal layer LCL is extremely thin as compared to a thickness of the substrate FS or the substrate B.S. The thickness of the liquid crystal layer LCL is about, for example, 3 to 4 μm in the example illustrated in FIG. 3.

<Equivalent Circuit of Display Device>

Next, an equivalent circuit of the display device will be described with reference to FIG. 4. FIG. 4 is a diagram illustrating the equivalent circuit of the display device according to the embodiment.

As illustrated in FIG. 4, the display section DP of the display device LCD1 includes the plurality of pixels Pix. The plurality of pixels Pix are provided on the substrate B.S. in the display region DPA and arrayed in a matrix in the X-axis direction and the Y-axis direction when seen in a plan view.

In addition, the display device LCD1 includes the plurality of scanning lines GL and the plurality of signal lines SL. The plurality of scanning lines GL are provided on the substrate B.S. (for example, see FIG. 2) in the display region DPA, extend in the X-axis direction, and are arrayed in the Y-axis direction. The plurality of signal lines SL are provided on the substrate B.S. in the display region DPA, extend in the Y-axis direction, and are arrayed in the X-axis direction. The plurality of signal lines SL and the plurality of scanning lines GL cross each other.

Each of the plurality of pixels Pix includes subpixels SPix each of which displays each color of R (red), G (green), and B (blue). Each of the subpixels SPix is provided in a region surrounded by the two neighboring scanning lines GL and the two neighboring signal lines SL but may have another configuration.

Each of the subpixels SPix includes a transistor Trd composed of a thin-film transistor, the pixel electrode PE connected to a drain electrode of the transistor Trd, and the common electrode CE facing the pixel electrode PE with the insulating layer interposed therebetween. Note that FIG. 4 illustrates a liquid crystal capacitor which equivalently represents the liquid crystal layer, and a holding capacitor formed between the common electrode CE and the pixel electrode PE, as a capacitor Clc. Note that a source electrode and the drain electrode of the thin-film transistor are interchanged with each other due to a polarity of potential as needed.

The drive circuit CC (see FIG. 1) of the display device LCD1 includes the video line drive circuit CS, the scanning line drive circuit CG, a control circuit CTL, and a common electrode drive circuit CM.

Each source electrode of the transistors Trd of the plurality of subpixels SPix arrayed in the Y-axis direction is connected to the signal line SL. In addition, each of the plurality of signal lines SL is connected to the video line drive circuit CS.

In addition, each gate electrode of the transistors Trd of the plurality of subpixels SPix arrayed in the X-axis direction is connected to the scanning line GL. In addition, each of the scanning lines GL is connected to the scanning line drive circuit CG.

The control circuit CTL controls the video line drive circuit CS, the scanning line drive circuit CG, and the common electrode drive circuit CM based on display data, a clock signal, and a display control signal such as a display timing signal which are transmitted from the outside of the display device.

The control circuit CTL converts the display data and the display control signal which are supplied from the outside, as needed, depending on the array of the subpixels of the display device, a display method, presence or absence of an RGB switch (not illustrated), presence or absence of the touch panel (not illustrated), or the like, to output the converted result to the video line drive circuit CS, the scanning line drive circuit CG, and the common electrode drive circuit CM.

<Configuration of Frame Region of Display Device>

Next, a configuration of the frame region of the display device will be described. Note that the display device in a case where a width of the frame region FLA2 in the Y-axis direction is large will be described below.

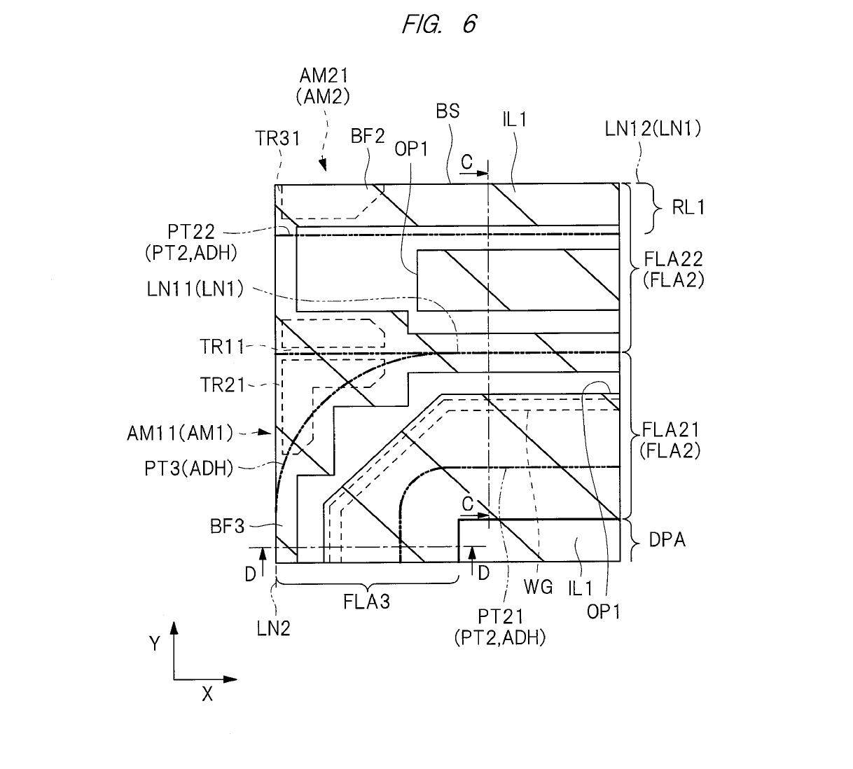

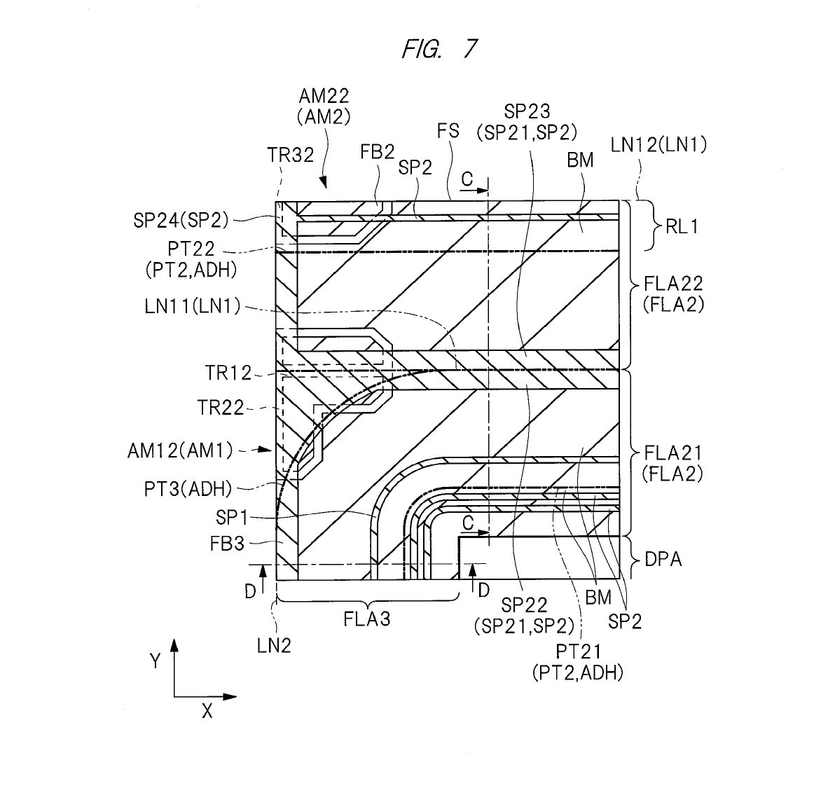

FIG. 5 is a plan view of the display device according to the embodiment. FIGS. 6 and 7 are plan views of the frame region of the display device according to the embodiment. FIGS. 6 and 7 illustrate an enlarged region RG1 of the display device illustrated in FIG. 5, which is surrounded by a two-dot chain line. In addition, FIG. 6 illustrates an alignment mark AM11 and the like formed on the substrate B.S. and the counter surface BSf of the substrate B.S., and FIG. 7 illustrates an alignment mark AM12 and the like formed on the substrate FS and the counter surface FSb of the substrate FS.

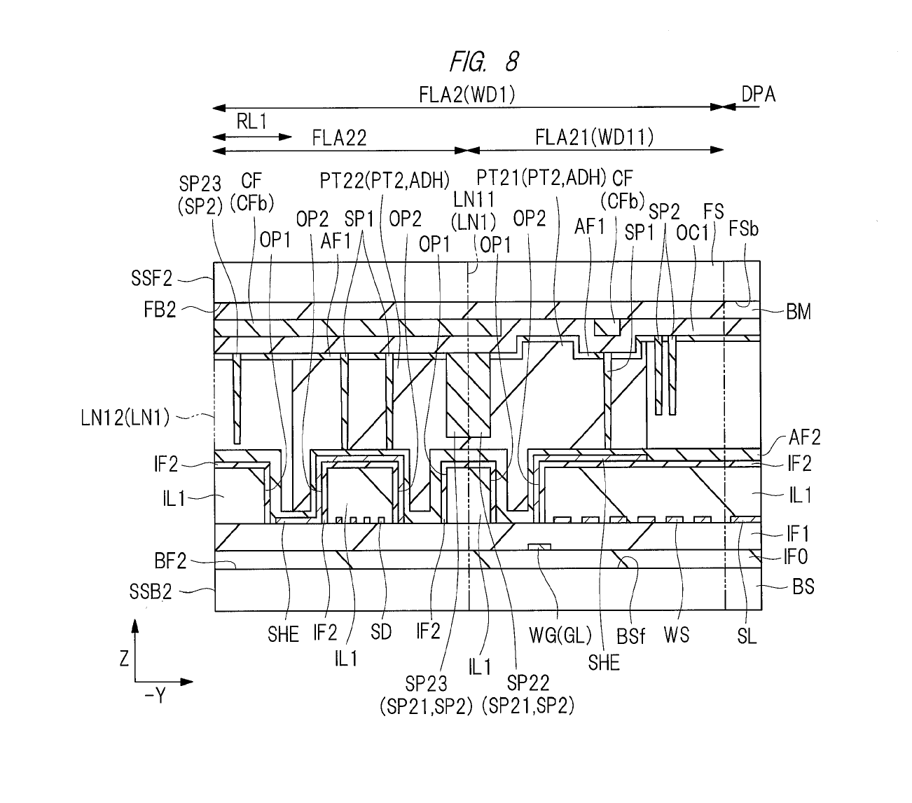

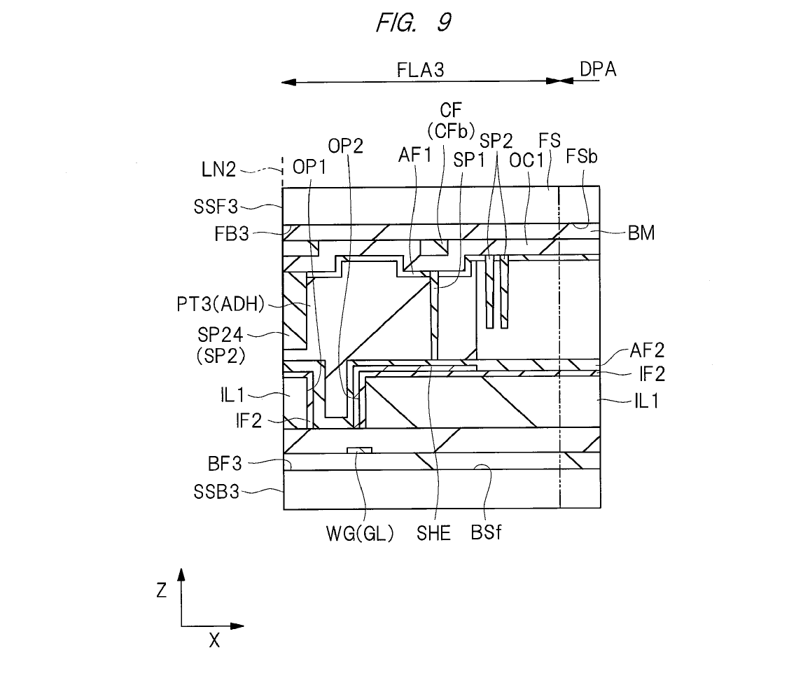

FIGS. 8 and 9 are cross-sectional views of the frame region of the display device according to the embodiment. FIG. 8 is the cross-sectional view taken along a line C-C of FIGS. 6 and 7, and FIG. 9 is the cross-sectional view taken along a line D-D of FIGS. 6 and 7. Note that FIGS. 6 and 7 do not illustrate some of parts illustrated in FIGS. 8 and 9 except for other parts required for description in order to simplify the understanding. In addition, FIGS. 8 and 9 do not illustrate the liquid crystal layer LCL (see FIG. 3).

The substrate B.S. includes the side BSs1, the side BSs2, the side BSs3, and the side BSs4 as described with reference to FIG. 1 and illustrated in FIG. 5. In addition, four side surfaces of the substrate B.S. corresponding to the side BSsl, the side BSs2, the side BSs3, and the side BSs4 will be referred to as a side surface SSB1, a side surface SSB2, a side surface SSB3, and a side surface SSB4, respectively. In addition, side surfaces of the substrate FS corresponding to the side BSs2, the side BSs3, and the side BSs4 will be referred to as a side surface SSF2, a side surface SSF3, and a side surface SSF4, respectively. Note that a side surface of the substrate FS on the side BSs1 side with respect to the display region DPA will be referred to as a side surface SSF1.

The frame region FLA2 includes frame regions FLA21 and FLA22. The frame region FLA21 is a part of the frame region FLA2 which is positioned on the display region DPA side, and the frame region FLA22 is apart of the frame region FLA2 which is positioned on the opposite side of the display region DPA.

As illustrated in FIGS. 6 to 8, a wire WG, an insulating film IF1, a wire WS, an interlayer resin film IL1, and the alignment film AF2 are provided on the counter surface BSf of the substrate B.S. in the frame region FLA2.

The wire WG is formed on the counter surface BSf of the substrate B.S. in the frame region FLA2. The wire WG is formed on the same layer as the scanning line GL, for example, and is made of metal such as chromium (Cr) and molybdenum (Mo) or an alloy thereof. That is, the wire WG is preferably composed of a conductive film having a light-shielding property, such as a metal film or an alloy film.

The insulating film IF1 is provided to cover the wire WG on the counter surface BSf of the substrate B.S. in the frame region FLA2. The insulating film IF1 is a transparent insulating film made of, for example, silicon nitride or silicon oxide.

Note that an insulating film IF0 may be formed between the counter surface BSf of the substrate B.S. and each of the wire WG and the insulating film IF1.

The wire WS is formed on the insulating film IF1 in the frame region FLA2. The wire WS is formed on the same layer as the signal line SL, for example, and is composed of a metal film having a multilayer structure in which aluminum (Al) is interposed between molybdenum (Mo) and the like, for example. That is, the wire WS is preferably composed of a conductive film having a light-shielding property such as a metal film.

The interlayer resin film ILl serving as a protection film or a planarization film is formed on the insulating film IF1 in the frame region FLA2 so as to cover the wire WS. The interlayer resin film ILl is made of, for example, an acrylic photosensitive resin.

An opening portion OP1 which penetrates the interlayer resin film IL1 and reaches the insulating film IF1 is formed in the interlayer resin film ILl in the frame region FLA2. An insulating film IF2 is provided on a bottom of the opening portion OP1, an inner wall of the opening portion OP1, and the interlayer resin film IL1. The insulating film IF2 is a transparent insulating film made of, for example, silicon nitride, silicon oxide, or the like.

An opening portion OP2 which penetrates the insulating film IF2 and reaches the insulating film IF1 is formed in the insulating film IF2 of a portion formed on the bottom of the opening portion OP1. The alignment film AF2 is formed on a bottom of the opening portion OP2, the insulating film IF2 of a portion formed on the inner wall of the opening portion OP1, and the insulating film IF2 of a portion formed on the interlayer resin film IL1. As described above, the alignment film AF2 is made of, for example, polyimide resin.

Note that a shield electrode SHE may be formed on a part of the bottom of the opening portion OP2, the insulating film IF2 of the portion formed on the inner wall of the opening portion OP1, and the insulating film IF2 of the portion formed on the interlayer resin film IL1. The shield electrode SHE is made of a transparent conductive material such as indium tin oxide (ITO) or indium zinc oxide (IZO). In this case, the alignment film AF2 is formed to cover the shield electrode SHE on the bottom of the opening portion OP2, the insulating film IF2 of the portion formed on the inner wall of the opening portion OP1, and the insulating film IF2 of the portion formed on the interlayer resin film IL1.

Meanwhile, the light-shielding film BM, the color filter CF, the resin layer OC1, the spacers SP1 and SP2, and the alignment film AF1 are provided on the counter surface FSb of the substrate FS in the frame region FLA2 as illustrated in FIGS. 6 to 8.

The light-shielding film BM is formed on the counter surface FSb of the substrate FS in the frame region FLA2. As described above, the light-shielding film BM is made of, for example, black resin or a metal having low reflectivity.

The color filter CF is formed between the light-shielding film BM and the substrate B.S. in the frame region FLA2. For example, the color filter pixel CFb of B (blue) is formed as the color filter CF.

The resin layer OC1 is formed in the frame region FLA2 so as to cover the light-shielding film BM and the color filter CF. As described above, the resin layer OC1 contains the thermosetting resin or the photocurable resin. Note that the color filter CF may be provided between the light-shielding film and the substrate FS.

The spacers SP1 and SP2 are formed between the resin layer OC1 and the substrate B.S. in the frame region FLA2. The spacers SP1 and SP2 protrude from the counter surface FSb of the substrate FS to the substrate B.S. side. The spacers SP1 and SP2 keep intervals between the substrate B.S. and the substrate FS. The spacers SP1 and SP2 are made of, for example, acrylic photosensitive resin. The color filter pixel CFb is provided between the spacers SP1 and SP2 and the substrate FS to control each height of the spacers SP1 and SP2. In addition, the spacer SP1 maybe interspersed conical spacers. Alternatively, the spacer SP2 may be a plurality of island-like spacers interspersed in the X-axis direction.

The height of the spacer SP1 from the substrate FS is higher than the height of the spacer SP2 from the substrate FS.

Note that the spacers SP1 and SP2 maybe provided on the counter surface BSf of the substrate B.S. In this case, the spacers SP1 and SP2 protrude from the counter surface BSf of the substrate B.S. to the substrate FS side.

The alignment film AF1 is formed between the resin layer OC1 and the substrate B.S. in the frame region FLA2. As described above, the alignment film AF1 is made of for example, polyimide resin. Note that the alignment film AF1 may be formed on a side surface and an upper surface of each of the spacers SP1 and SP2 although not illustrated in FIG. 8.

As illustrated in FIG. 8, the seal ADH is provided between the alignment film AF1 and the alignment film AF2. That is, the seal ADH is an adhesive portion which is provided between the substrate B.S. and the substrate FS and allows the substrate B.S. and the substrate FS to adhere to each other. In addition, when seen in a plan view, the seal ADH includes a portion PT1 provided in the frame region FLA1, a portion PT2 provided in the frame region FLA2, a portion PT3 provided in the frame region FLA3, and a portion PT4 provided in the frame region FLA4, as illustrated in FIG. 5.

<Problem in Changing Width of Frame Region>

In a display device, there is a case where the display device is designed by changing only a width of the frame region FLA2 in the Y-axis direction without changing each width of the frame regions FLA3 and FLA4 in the X-axis direction. Such a change of only the width of the frame region FLA2 is made based on a request from a customer for prioritizing the strength of the display device or prioritizing reduction of the frame region.

In the past, when there is a request for change of the width of the frame region FLA2 and even if it is possible to make shapes and arrangements other than the widths of the frame regions FLA2 the same, in order to manufacture two types of display devices having different widths of the frame regions FLA2 in the Y-axis direction, it has been necessary to separately prepare a set of a plurality of photomasks used for photolithography in processes of manufacturing the display devices, respectively. Accordingly, costs required for the manufacture of the display devices have increased, or a period required for the manufacture of the display devices has increased.

<Arrangements of Seal and Spacer in Frame Region>

A spacer SP21 serving as the spacer SP2 is arranged in the frame region FLA2 in the display device according to the present embodiment. The portion PT2 of the seal ADH includes a portion PT21 and a portion PT22. The portion PT21 of the seal ADH is arranged on the display region DPA side with respect to the spacer SP21 in the Y-axis direction, and the portion PT22 of the seal ADH is arranged on the opposite side of the portion PT21 with the spacer SP21 interposed therebetween. An end BF3 on one side of the counter surface BSf of the substrate B.S. in the X-axis direction, or an end FB3 on one side of the counter surface FSb of the substrate FS in the X-axis direction is covered by the portion PT3 of the seal ADH.

In other words, the frame region FLA21 serving as a first part of the frame region FLA2 is arranged on the display region DPA side with respect to the spacer SP21, and the frame region FLA22 serving as a second part of the frame region FLA2 is arranged on the opposite side of the frame region FLA21 with the spacer SP21 interposed therebetween. The seal ADH is provided in the frame regions FLA21 and FLA22 when seen in a plan view. The spacer SP21 is formed from a first end of the substrate FS on the frame region FLA3 side to a second end of the substrate FS on the frame region FLA4 side at a boundary between the frame region FLA21 and the frame region FLA22. Further, the spacer SP21 is in contact with the portion PT21 of the seal ADH on the frame region FLA21 side, and the spacer SP21 is in contact with the portion PT22 of the seal ADH on the frame region FLA22 side.

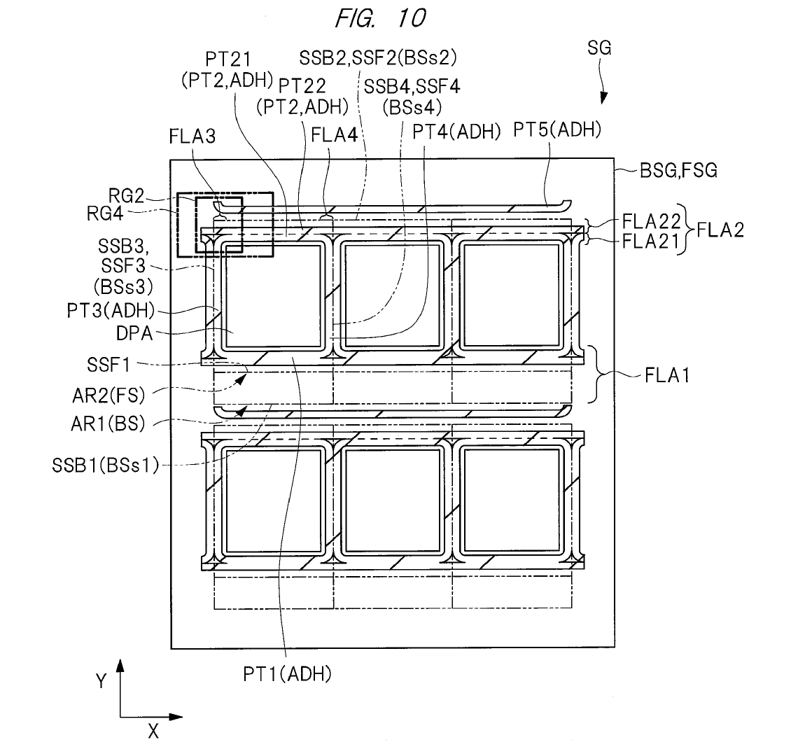

When the above-described display device is manufactured, it is possible to use any of two types of scribe lines including a scribe line LN11 and a scribe line LN12, the scribe lines extending in the X-axis direction at the time of dividing a substrate assembly (motherboard) SG as will described later with reference to FIGS. 10 to 13. The scribe line LN11 passes through the spacer SP21 when seen in a plan view. The scribe line LN12 is provided on the opposite side of the display region DPA with the scribe line LN11 interposed therebetween and passes through a region RL1 in which the seal ADH is not provided when seen in a plan view.

When the scribe line LN11 is used as the scribe line, a force applied to the substrate assembly SG during a scribing process, for example, is symmetrically distributed with the scribe line LN11 as a center, and accordingly, it is possible to easily perform the scribing process as will be described later with reference to FIGS. 10 to 13. Meanwhile, it is also possible to easily perform the scribing process when the scribe line LN12 is used as the scribe line as will be described later with reference to FIGS. 10 to 13. Accordingly, it is possible to easily change the width of the frame region FLA2 in the Y-axis direction between two types of widths as will be described later with reference to FIGS. 10 to 13.

Meanwhile, one type of scribe line can be used as a scribe line LN2 which is provided on both sides with respect to the display region DPA in the X-axis direction and extends in the Y-axis direction. In this case, positions of both side surfaces SSB3 and SSB4 (see FIG. 5) of the substrate B.S. in the X-axis direction are fixed, positions of both side surfaces SSF3 and SSF4 (see FIG. 5) of the substrate FS in the X-axis direction are fixed, and each width of the frame regions FLA3 and FLA4 (see FIG. 5) in the X-axis direction is also fixed.

Accordingly, in the display device according to the present embodiment, it is possible to change only the width of the frame region FLA2 in the Y-axis direction without changing the width of the frame region FLA3 in the X-axis direction and the width of the frame region FLA4 in the X-axis direction. Such a configuration of changing only the width of the frame region FLA2 is important from a viewpoint of adjusting balance between reduction in width of the frame region FLA2 and securement of the strength of the display device.

Accordingly, in the display device according to the present embodiment, in order to manufacture two types of display devices having different widths of the frame regions FLA2 in the Y-axis direction, it is unnecessary to separately prepare a set of a plurality of photomasks used for photolithography in processes of manufacturing the display devices, respectively. Thus, it is possible to reduce the costs required for the manufacture of the two types of display devices having different widths of the frame regions FLA2 in the Y-axis direction. Alternatively, it is possible to shorten the period required for the manufacture of two types of display devices having different widths of the frame regions FLA2 in the Y-axis direction. Accordingly, it is possible to easily manufacture the two types of display devices having different widths of the frame regions FLA2 in the Y-axis direction.

That is, according to the present embodiment, it is possible to select a width of the frame region FLA2 by providing two cutting lines in the frame region FLA2 and changing a cutting position.

The spacer SP21 extends in the X-axis direction. Accordingly, it is possible to more easily perform the scribing process as will be described later with reference to FIGS. 10 to 13.

An end BF2 of the counter surface BSf of the substrate B.S. in the Y-axis direction and an end FB2 of the counter surface FSb of the substrate FS in the Y-axis direction are exposed from the seal ADH. In other words, the end BF2 of the substrate B.S. and the end

FB2 of the substrate FS in the frame region FLA22 are exposed from the seal ADH. That is, the seal ADH is spaced apart from the side surface SSB2 (see FIG. 8) of the substrate B.S. in the Y-axis direction and the side surface SSF2 (see FIG. 8) of the substrate FS in the Y-axis direction when seen in a plan view. In this case, as will be described later with reference to FIGS. 10 to 13, it is possible to easily perform the scribing process along the scribe line LN12. Meanwhile, the seal ADH may be also provided in the region RL1 in which the scribe line LN12 is enclosed.

Preferably, the display device according to the present embodiment includes an alignment mark AM1 for positioning. The alignment mark AM1 is provided on the substrate B.S. or the substrate FS and is arranged at the same position as the spacer SP21 in the Y-axis direction. In other words, the alignment mark AM1 is superimposed on the spacer SP21 in the Y-axis direction. Further, the alignment mark AM1 is provided in the frame region FLA21 at the boundary between the frame region FLA21 and the frame region FLA22. As illustrated in FIGS. 6 and 7, the alignment mark AM1 formed on the substrate B.S. will be referred to as the alignment mark AM11, and the alignment mark AM1 formed on the substrate FS will be referred to as the alignment mark AM12.

It is possible to improve the positional accuracy in the scribing process by performing the scribing process through use of the scribe line LN11 that passes through the alignment marks AM11 and AM12 when seen in a plan view.

Preferably, the display device according to the present embodiment includes an alignment mark AM2 for positioning. The alignment mark AM2 is provided in the end BF2 of the counter surface BSf of the substrate B.S. in the Y-axis direction or the end FB2 of the counter surface FSb of the substrate FS in the Y-axis direction. In other words, the alignment mark AM2 is provided in the end BF2 or the end FB2 in the frame region FLA22. As illustrated in FIGS. 6 and 7, the alignment mark AM2 formed on the substrate B.S. will be referred to as an alignment mark AM21, and the alignment mark AM2 formed on the substrate FS will be referred to as the alignment mark AM22.

It is possible to improve the positional accuracy in the scribing process by performing the scribing process through use of the scribe line LN21 that passes through the alignment marks AM21 and AM22 when seen in a plan view.

Preferably, the alignment marks AM11 and AM21 are formed on the same layer as the plurality of scanning lines GL or the plurality of signal lines SL. Each of the scanning line GL and the signal line SL is composed of the conductive film having the light-shielding property as described above. Thus, it is possible to enhance visibility of the alignment marks AM11 and AM21, and the accuracy in positioning performed through use of the alignment marks AM11 and AM21 by forming the alignment marks AM11 and AM21 on the same layer as the plurality of scanning lines GL or the plurality of signal lines SL.

Preferably, the alignment marks AM12 and AM22 are formed on the same layer as the light-shielding film BM. The light-shielding film BM is composed of the film having the light-shielding property as described above. Thus, it is possible to enhance the visibility of the alignment marks AM12 and AM22, and the accuracy in positioning performed through use of the alignment marks AM12 and AM22 by forming the alignment marks AM12 and AM22 on the same layer as the light-shielding film BM.

Preferably, the alignment mark AM2 has a shape different from a shape of the alignment mark AM1. Accordingly, it is possible to prevent misidentification between the alignment mark AM1 and the alignment mark AM2 and to perform the scribing process by reliably selecting a desired scribe line between the scribe line LN11 and the scribe line LN12.

Preferably, a circuit wire such as the wire WS is arranged in the frame region FLA21. As described above, the frame region FLA21 is the part of the frame region FLA2 positioned on the display region DPA side and the part positioned on the display region DPA side with respect to the center of the spacer SP21. In contrast, in the frame region FLA22, dummy patterns GD and SD to be described later may be arranged, but the circuit wire such as the wire WS is not arranged. As described above, the frame region FLA22 is the part of the frame region FLA2 positioned on the opposite side of the display region DPA and the part arranged on the opposite side of the display region DPA with respect to the center of the spacer SP21.

According to such an arrangement, it is unnecessary to change an arrangement of the circuit wire such as the wire WS, for example, even in the case of changing only the width of the frame region FLA2 in the Y-axis direction, and thus, it is possible to easily design two types of display devices obtained by changing only the width of the frame region FLA2 in the Y-axis direction. In addition, it is possible to further improve the strength of the display device by doubly sealing a portion between the substrate B.S. and the substrate FS with the two portions PT1 and PT2 included in the seal ADH in the display device having the larger width of the frame region FLA2 in the Y-axis direction.

Note that it is possible to set a width WD1 of the frame region FLA2 in the Y-axis direction to, for example, about 1 mm. In addition, it is possible to set a width WD11 of the portion (the frame region FLA21) of the frame region FLA2 which is arranged on the display region DPA side with respect the center of the spacer SP1 in the Y-axis direction to, for example, about 0.5 mm.

<Method of Manufacturing Display Device>

Next, a method of manufacturing the display device will be described.

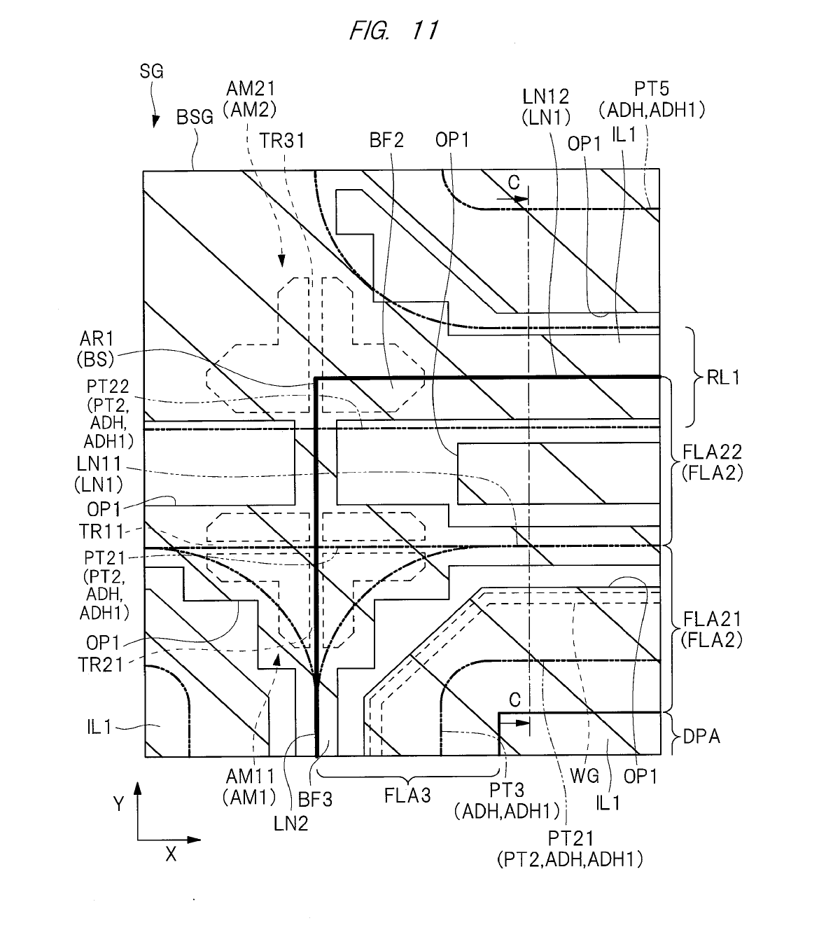

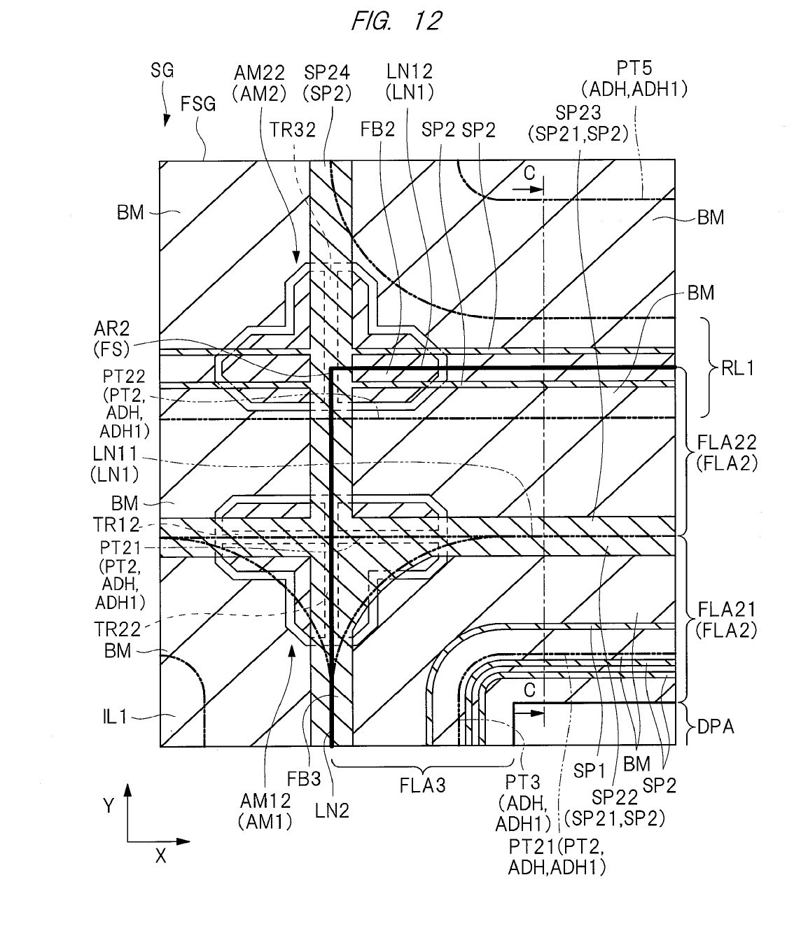

FIGS. 10 to 12 are plan views of the display device during the manufacturing process according to the embodiment. FIGS. 11 and 12 illustrate an enlarged region RG2 of the substrate assembly SG illustrated in FIG. 10, which is surrounded by a two-dot chain line. In addition, FIG. 11 illustrates the alignment mark AM11 and the like formed on a motherboard BSG and the counter surface BSf of the motherboard BSG, and FIG. 12 illustrates the alignment mark AM12 and the like formed on a motherboard FSG and the counter surface FSb of the motherboard FSG.

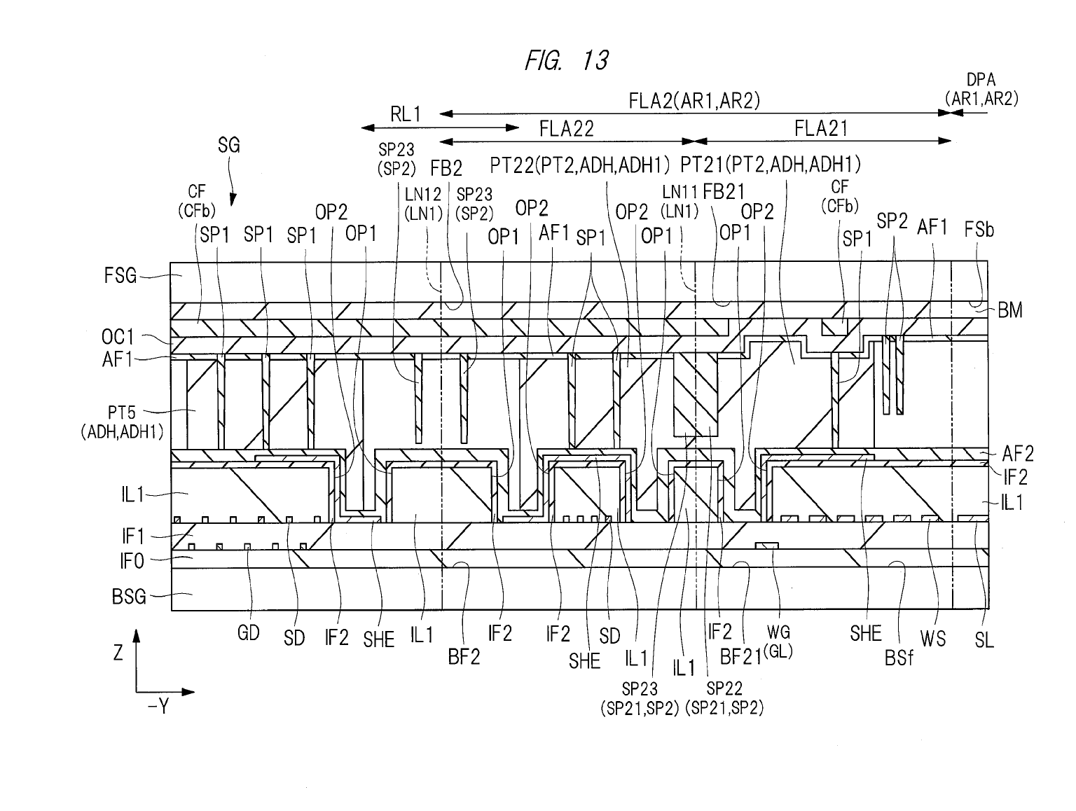

FIG. 13 is a cross-sectional view of the display device during the manufacturing process according to the embodiment. Note that FIGS. 11 and 12 do not illustrate some of parts illustrated in FIG. 13 except for other parts required for description in order to simplify the understanding. In addition, FIG. 13 does not illustrate the liquid crystal layer LCL (see FIG. 3).

First, the motherboard BSG is prepared as illustrated in FIG. 13. The motherboard BSG includes a plurality of display panel formation regions AR1 which are substrate formation regions as a region of the counter surface BSf serving as the main surface. As illustrated in FIG. 10, the plurality of display panel formation regions AR1 are arrayed in a matrix in the X-axis direction and the Y-axis direction, for example. A process of forming the seal ADH to be described later is performed, and then, the motherboard BSG is divided into each of the plurality of display panel formation regions AR1, so that a plurality of substrates B.S. are formed. That is, the substrate B.S. is an individual substrate obtained by dividing the motherboard BSG into each of the plurality of display panel formation regions AR1.

As illustrated in FIG. 10, the counter surface BSf of the display panel formation region AR1 includes the display region DPA and the frame regions FLA1, FLA2, FLA3, and FLA4 as the frame region FLA. The frame region FLA1 is arranged on one side in the Y-axis direction with respect to the display region DPA when seen in a plan view. The semiconductor chip CHP is provided in the frame region FLA1 of the display panel formation region AR1. The frame region FLA2 is arranged on the opposite side of the frame region FLA1 with the display region DPA interposed therebetween. The frame region FLA3 is arranged on one side in the X-axis direction which crosses and is preferably orthogonal to the Y-axis direction with respect to the display region DPA when seen in a plan view. The frame region FLA4 is arranged on the opposite side of the frame region FLA3 with the display region DPA interposed therebetween.

Next, the plurality of pixels are provided in each of the plurality of display panel formation regions AR1.

In this case, in the frame region FLA2, as illustrated in FIG. 13, the wire WG is formed on the counter surface BSf of the display panel formation region AR1, and the insulating film IF1 is formed on the counter surface BSf of the display panel formation region AR1 so as to cover the wire WG. Note that the insulating film IF0 may be formed between the counter surface BSf of the motherboard BSG and each of the wire WG and the insulating film IF1.

In addition, the wire WS is formed on the insulating film IF1 in the frame region FLA2, and the interlayer resin film IL1 serving as the protection film or the planarization film is formed on the insulating film IF1 so as to cover the wire WS. The opening portion OP1 which penetrates the interlayer resin film IL1 and reaches the insulating film IF1 is formed in the interlayer resin film IL1, and the insulating film IF2 is formed on the bottom of the opening portion OP1, the inner wall of the opening portion OP1, and the interlayer resin film IL1. In addition, the opening portion OP2 which penetrates the insulating film IF2 and reaches the insulating film IF1 is formed in the insulating film IF2 of the portion formed on the bottom of the opening portion OP1. The alignment film AF2 is formed on the bottom of the opening portion OP2, the insulating film IF2 of the portion formed on the inner wall of the opening portion OP1, and the insulating film IF2 of the portion formed on the interlayer resin film IL1.

Note that the plurality of scanning lines GL (see FIG. 4) which extend in the X-axis direction and are arrayed in the Y-axis direction when seen in a plan view are formed in the display panel formation region AR1 at the time of forming the wire WG. In addition, the plurality of signal lines SL (see FIG. 4) which extend in the Y-axis direction and are arrayed in the X-axis direction when seen in a plan view are formed in the display panel formation region AR1 at the time of forming the wire WS.

In addition, the motherboard FSG is prepared as illustrated in FIG. 13. The motherboard FSG includes a plurality of display panel formation regions AR2 which are substrate formation regions as a region of the counter surface FSb serving as the main surface. As illustrated in FIG. 10, the display panel formation regions AR2 are arrayed in a matrix in the X-axis direction and the Y-axis direction, for example. The process of forming the seal ADH to be described later is performed, and then, the motherboard FSG is divided into each of the plurality of displaypanel formation regions AR2, so that a plurality of substrates FS are formed. That is, the substrate FS is an individual substrate obtained by dividing the motherboard FSG into each of the plurality of display panel formation regions AR2.

Next, the spacers SP1 and SP2 which are protruded from the counter surface BSf of the display panel formation region AR1 or the counter surface FSb of the display panel formation region AR2 are provided. The spacers SP1 and SP2 may be formed in any of the motherboards BSG and FSG, and a description will be given regarding an example in which the spacers SP1 and SP2 are formed in the motherboard FSG, hereinafter.

As illustrated in FIG. 13, the light-shielding film BM is formed on the counter surface FSb of the display panel formation region AR2, the color filter pixel CFb of B (blue), for example, as the color filter CF is formed on the light-shielding film BM, and the resin layer OC1 is formed on the light-shielding film BM on the substrate B.S. side so as to cover the color filter CF in the frame region FLA2.

The spacers SP1 and SP2 are formed on the resin layer OC1 on the substrate B.S. side. Note that, as described above, a thickness dimension of the spacer SP1 is thicker than a thickness dimension of the spacer SP2, and a lower surface of the spacer SP1 is in contact with the alignment film AF2 while a lower surface of the spacer SP2 is not in contact with the alignment film AF2. In addition, the spacer SP21 is provided as the spacer SP2. The spacer SP21 is provided such that the spacer SP21 is arranged in the frame region FLA2 when seen in a plan view at the time of arranging the motherboard BSG and the motherboard FSG to face each other.

Note that the spacer SP21 may be provided in the motherboard BSG. In this case, the spacer SP21 is arranged in the frame region FLA2.

The alignment film AF1 is formed on the resin layer OC1. As described above, the alignment film AF1 is made of, for example, polyimide resin.

Next, a sealing member ADH1 serving as the resin film is formed on the counter surface BSf in the display panel formation region AR1 or the counter surface FSb in the display panel formation region AR2. For example, a UV-curable resin is coated by printing or drawing as a material to form the sealing member ADH1. The sealing member ADH1 may be formed in any of the motherboards BSG and FSG, and herein, a description will be given regarding an example in which the sealing member ADH1 is formed in the motherboard FSG.

Next, the motherboard BSG and the motherboard FSG are arranged to face each other as illustrated in FIG. 13. The motherboard BSG and the motherboard FSG are arranged to face each other in a state in which the counter surface BSf of the motherboard BSG and the counter surface FSb of the motherboard FSG face each other. In this case, the spacer SP1 formed in the display panel formation region AR2 is brought into contact with the alignment film AF2 formed in the display panel formation region AR1, and accordingly, it is possible to keep an interval between the display panel formation region AR1 and the display panel formation region AR2.

Next, the sealing member ADH1 is subjected to curing to form the seal ADH which is composed of the cured sealing member ADH1 and serves as the adhesive portion, and the motherboard BSG and the motherboard FSG are allowed to adhere to each other via the seal ADH. For example, the sealing member ADH1 is irradiated with ultraviolet rays to cure the sealing member, and heat curing treatment is further performed to fully cure the sealing member. Accordingly, the motherboard BSG and the motherboard FSG are allowed to adhere (are bonded) to each other via the seal ADH, so that the substrate (display panel) assembly SG including the motherboard BSG and the motherboard FSG adhering to the motherboard BSG via the seal ADH is formed. The liquid crystals may be sealed in the respective display panels at this point of time or the liquid crystals may be injected thereafter.

In this process, the seal ADH which includes the portion PT1 provided in the frame region FLA1, the portion PT2 provided in the frame region FLA2, the portion PT3 provided in the frame region FLA3, and the portion PT4 provided in the frame region FLA4 when seen in a plan view is formed. The portion PT2 of the seal ADH includes the portion PT21 and the portion PT22. In addition, the portion PT21 is arranged on one side with respect to the spacer SP21, that is, the side on which the semiconductor chip CHP is formed, and the portion PT22 is arranged on the opposite side of the portion PT21 with the spacer SP21 interposed therebetween. Note that a portion of the seal ADH which is provided outside the display panel formation regions AR1 and AR2 will be referred to as a portion PT5.

Next, the substrate assembly SG is divided, and each of the motherboards BSG and FSG is divided, so that the substrate B.S. including the display panel formation region AR1 and the substrate FS including the display panel formation region AR2 and adhering to the substrate B.S. via the seal ADH are formed.

When the substrates B.S. and FS are formed by dividing each of the motherboards BSG and FSG, it is possible to use any of the two types of scribe lines including the scribe line LN11 and the scribe line LN12 as the scribe line extending in the X-axis direction. In this case, the display panel formation region AR1 or AR2 serving as the substrate formation region is determined whether to be scribed by a first size or a second size larger than the first size. The scribe line LN11 passes through the spacer SP21 when seen in a plan view. The scribe line LN12 is provided on the opposite side of the display region DPA with the scribe line LN11 interposed therebetween and passes through the region RL1 in which the seal ADH is not provided when seen in a plan view.

When the scribe line LN11 is used as the scribe line, two portions SP22 and SP23 of the spacer SP21 respectively arranged on both sides with respect to the scribe line LN11 are symmetrically arranged with the scribe line LN11 as a center. Thus, a force applied to the motherboard BSG or the motherboard FSG during the scribing process is symmetrically distributed with the scribe line LN11 as the center, for example, so that the scribing process can be easily performed.

In this case, the substrate B.S. including apart of the display panel formation region AR1 and the substrate FS including a part of the display panel formation region AR2 and adhering to the substrate B.S. via the seal ADH are formed. In addition, the end BF3 on one side of the counter surface BSf of the substrate B.S. in the X-axis direction or the end FB3 on one side of the counter surface FSb of the substrate FS in the X-axis direction is covered by the portion PT3 of the seal ADH. In addition, an end BF21 of the counter surface BSf of the substrate B.S. on the opposite side of the semiconductor chip CHP in the Y-axis direction or an end FB21 of the counter surface FSb of the substrate FS in the Y-axis direction is covered by the spacer SP21.

In contrast, when the scribe line LN12 is used as the scribe line, any of the substrates B.S. and FS positioned near the scribe line LN12 do not receive the force from the seal ADH when seen in a plan view. Thus, the scribing process can also be easily performed even in the case of using the scribe line LN12.

In this case, the substrate B.S. including the entire display panel formation region AR1 and the substrate FS including the entire display panel formation region AR2 and adhering to the substrate B.S. via the seal ADH are formed (see FIG. 8). In addition, the end BF3 on one side of the counter surface BSf of the substrate B.S. in the X-axis direction or the end FB3 on one side of the counter surface FSb of the substrate FS in the X-axis direction is covered by the portion PT3 of the seal ADH. Meanwhile, the end BF2 of the counter surface BSf of the substrate B.S. in the Y-axis direction and the end FB2 of the counter surface FSb of the substrate FS in the Y-axis direction are exposed from the seal ADH.

That is, the scribing process can be easily performed in the case of using any of the scribe lines LN11 and LN12 as the scribe line LN1. Accordingly, a position of the side surface SSB2 of the substrate B.S. on the opposite side of the semiconductor chip CHP in the Y-axis direction (see FIG. 10) can be easily changed between two positions, and thus, it is possible to easily change the width of the frame region FLA2 in the Y-axis direction between two types of widths. In addition, a position of the side surface SSF2 of the substrate FS on the opposite side of the semiconductor chip CHP in the Y-axis direction (see FIG. 10) can be easily changed between two positions, and thus, it is possible to easily change the width of the frame region FLA2 in the Y-axis direction between two types of widths.

Meanwhile, it is possible to use one type of scribe line as the scribe line LN2 which is provided on both sides with respect to the display region DPA in the X-axis direction and extends in the Y-axis direction. In this case, the positions of both side surfaces SSB3 and SSB4 of the substrate B.S. in the X-axis direction (see FIG. 10) are fixed, the positions of both side surfaces SSF3 and SSF4 of the substrate FS in the X-axis direction (see FIG. 10) are fixed, and the widths of the frame regions FLA3 and FLA4 in the

X-axis direction (see FIG. 10) are also fixed.

Accordingly, in the present embodiment, it is possible to change only the width of the frame region FLA2 in the Y-axis direction without changing the widths of the frame regions FLA3 and FLA4 in the X-axis direction. In this case, it is unnecessary to separately prepare the set of the plurality of photomasks used for photolithography in the processes of manufacturing the display devices, respectively, in order to manufacture the two types of display devices having the different widths of the frame regions FLA2 in the Y-axis direction.

Preferably, the spacer SP21 extends in the X-axis direction. Accordingly, the scribe line LN11 overlaps with the spacer SP21 in any position in the X-axis direction when seen in a plan view, and thus, the same optimal condition for the scribing process is given in any position in the X-axis direction, for example. In addition, the distribution of rigidity or hardness of the substrate assembly SG is symmetric with the scribe line LN11 as the center by arranging the spacer SP21 to straddle both sides of the scribe line LN11. Accordingly, it is possible to more easily perform the scribing process. The spacer SP21 of the scribe line LN11 may be a plurality of island-like divided spacers interspersed in the X-axis direction. The spacer SP21 is configured not to be in contact with the facing substrate but may be in contact with the substrate. In addition, it may be configured such that the spacer SP21 itself is not provided.

In addition, the end BF2 of the counter surface BSf of the substrate B.S. and the end FB2 of the counter surface FSb of the substrate FS are preferably exposed from the seal ADH when the scribing process is performed through use of the scribe line LN12. There is a case where the scribing process is more easily performed in the region in which the seal ADH is not provided than in the region in which the seal ADH is provided. In this case, the end BF2 of the counter surface BSf of the substrate B.S. and the end FB2 of the counter surface FSb of the substrate FS are exposed from the seal ADH, and accordingly, it is possible to easily perform scribing along the scribe line LN12.

In this case, more preferably, the spacers SP23 which are arranged on both sides of the scribe line LN12 and serve as the two spacers SP2 in the region RL1 in which the scribe line LN12 is enclosed when seen in a plan view may be provided in the substrate assembly SG. The two spacers SP23 are arranged on both sides of the scribe line LN12, and accordingly, the distribution of rigidity or hardness of the substrate assembly is symmetric with the scribe line LN12 as the center. Accordingly, it is possible to more easily perform scribing through use of the scribe line LN12.

However, it is not essential that the seal ADH is not provided in the region RL1 in which the scribe line LN12 is enclosed, and the seal ADH may also be provided in the region RL1. Accordingly, the end BF2 of the counter surface BSf of the substrate B.S. and the end FB2 of the counter surface FSb of the substrate FS may be covered by the seal ADH.

Preferably, the substrate assembly SG includes the spacer SP24 as the spacers SP2. The spacer SP24 extends in the Y-axis direction. The scribe line LN2 overlaps with the spacer SP24 in any position in the Y-axis direction when seen in a plan view. Accordingly, the same optimal condition for the scribing process is given in any position in the Y-axis direction, for example. In addition, the distribution of rigidity or hardness of the substrate assembly SG is symmetric with the scribe line LN2 as the center by arranging the spacer SP24 to straddle both sides of the scribe line LN2. Accordingly, it is possible to more easily perform the scribing process.

Preferably, the substrate assembly SG includes the alignment mark AM1. The alignment mark AM1 is provided in the display panel formation region AR1 of the motherboard BSG or the display panel formation region AR2 of the motherboard FSG. In addition, the alignment mark AM1 is provided such that the alignment mark AM1 is arranged at the same position as the spacer SP21 in the Y-axis direction at the time of arranging the motherboard BSG and the motherboard FSG to face each other. That is, the alignment mark AM1 is provided so as to be superimposed on the spacer SP21 in the Y-axis direction. When the display panel formation region AR1 or AR2 is scribed by the above-described first size, the vicinity of the alignment mark AM1 is cut. In addition, when the display panel formation region AR1 or AR2 is scribed by the above-described first size, the scribing is performed along the spacer SP21. As illustrated in FIGS. 11 and 12, the alignment mark AM1 formed in the substrate B.S. is referred to as the alignment mark AM11, and the alignment mark AM1 formed in the substrate FS is referred to as the alignment mark AM12.

The scribe line LN11 extending in the X-axis direction passes through the alignment marks AM11 and AM12 when seen in a plan view. Accordingly, it is possible to perform the scribing process along the scribe line LN11 through use of the alignment marks AM11 and AM12, and thus, it is possible to improve the positional accuracy of the scribing process.

Preferably, the substrate assembly SG includes the alignment mark AM2. The alignment mark AM2 is provided in the display panel formation region AR1 of the motherboard BSG or the display panel formation region AR2 of the motherboard FSG. When the display panel formation region AR1 or AR2 is scribed by the above-described second size, the vicinity of the alignment mark AM2 which is spaced apart from the plurality of pixels farther than the alignment mark AM1 is cut. In addition, the alignment mark AM2 is provided such that the alignment mark AM2 overlaps with the end BF2 of the counter surface BSf of the display panel formation region AR1 or the end FB2 of the counter surface FSb of the display panel formation region AR2 at the time of arranging the motherboard BSG and the motherboard FSG to face to each other. As illustrated in FIGS. 11 and 12, the alignment mark AM2 formed in the substrate B.S. is referred to as the alignment mark AM21, and the alignment mark AM2 formed in the substrate FS is referred to as the alignment mark AM22.

The scribe line LN12 extending in the X-axis direction passes through the alignment marks AM21 and AM22 when seen in a plan view. Accordingly, it is possible to perform the scribing process along the scribe line LN21 using the alignment marks AM21 and AM22, and accordingly, it is possible to improve the positional accuracy of the scribing process.

Preferably, the alignment mark AM2 having a shape different from a shape of the alignment mark AM1 is provided. Accordingly, it is possible to prevent misrecognition between the alignment mark AM1 and the alignment mark AM2 and to perform the scribing process by reliably selecting a desired scribe line between the scribe line LN11 and the scribe line LN12.

As illustrated in FIG. 11, for example, a trench portion TR11 extending in the X-axis direction and a trench portion TR21 extending in the Y-axis direction are formed in the alignment mark AM11. In the alignment mark AM21, a trench portion TR31 extending in the Y-axis direction is formed, but a trench portion extending in the X-axis direction is not formed. Accordingly, it is possible to make the shape of the alignment mark AM21 different from the shape of the alignment mark AM11.

In addition, it is possible to arrange the scribe line LN11 to pass through the trench portion TR11 and arrange the scribe line LN2 to pass through the trench portions TR21 and TR31 when seen in a plan view. The trench portion TR11 is formed, and accordingly, it is possible to easily improve the positional accuracy at the time of performing the scribing process along the scribe line LN11. In addition, the trench portions TR21 and TR31 are formed, and accordingly, it is possible to easily improve the positional accuracy at the time of performing the scribing process along the scribe line LN2. Since one type of scribe line is used as the scribe line LN2 extending in the Y-axis direction, the scribing process of the motherboard BSG may be performed through use of any of the alignment mark AM11 in which the trench portion TR21 is formed and the alignment mark AM21 in which the trench portion TR31 is formed.

As illustrated in FIG. 12, for example, a trench portion TR12 extending in the X-axis direction and a trench portion TR22 extending in the Y-axis direction are formed in the alignment mark AM12. In the alignment mark AM22, a trench portion TR32 extending in the Y-axis direction is formed, but a trench portion extending in the X-axis direction is not formed. Accordingly, it is possible to make a shape of the alignment mark AM22 different from a shape of the alignment mark AM12.

In addition, it is possible to arrange the scribe line LN12 to pass through the trench portion TR12 and arrange the scribe line LN2 to pass through the trench portions TR22 and TR32 when seen in a plan view. The trench portion TR12 is formed, and accordingly, it is possible to easily improve the positional accuracy at the time of performing the scribing process along the scribe line LN11. In addition, the trench portions TR22 and TR32 are formed, and accordingly, it is possible to easily improve the positional accuracy at the time of performing the scribing process along the scribe line LN2. Since one type of scribe line is used as the scribe line LN2 extending in the Y-axis direction, the scribing process of the motherboard FSG may be performed through use of any of the alignment mark AM12 in which the trench portion TR22 is formed and the alignment mark AM22 in which the trench portion TR32 is formed.

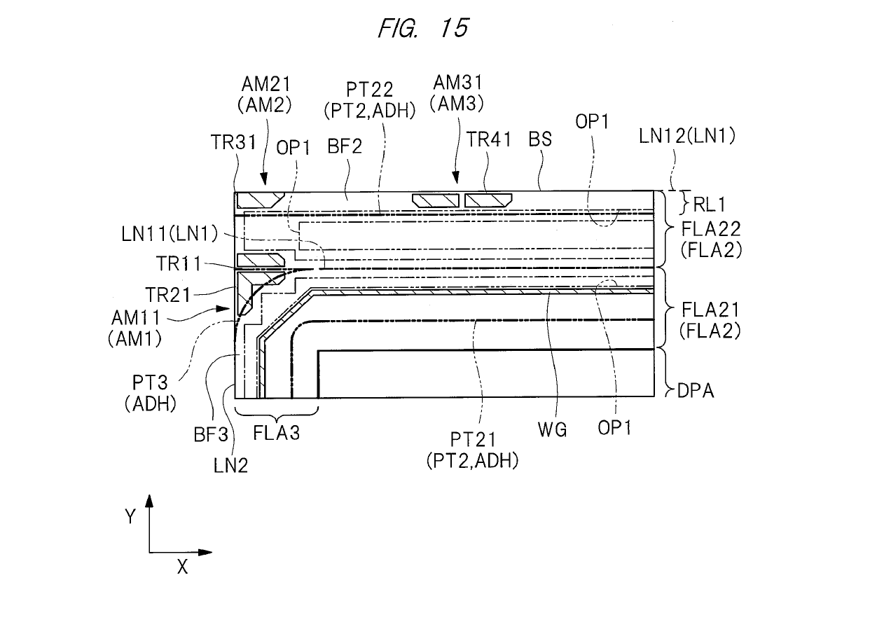

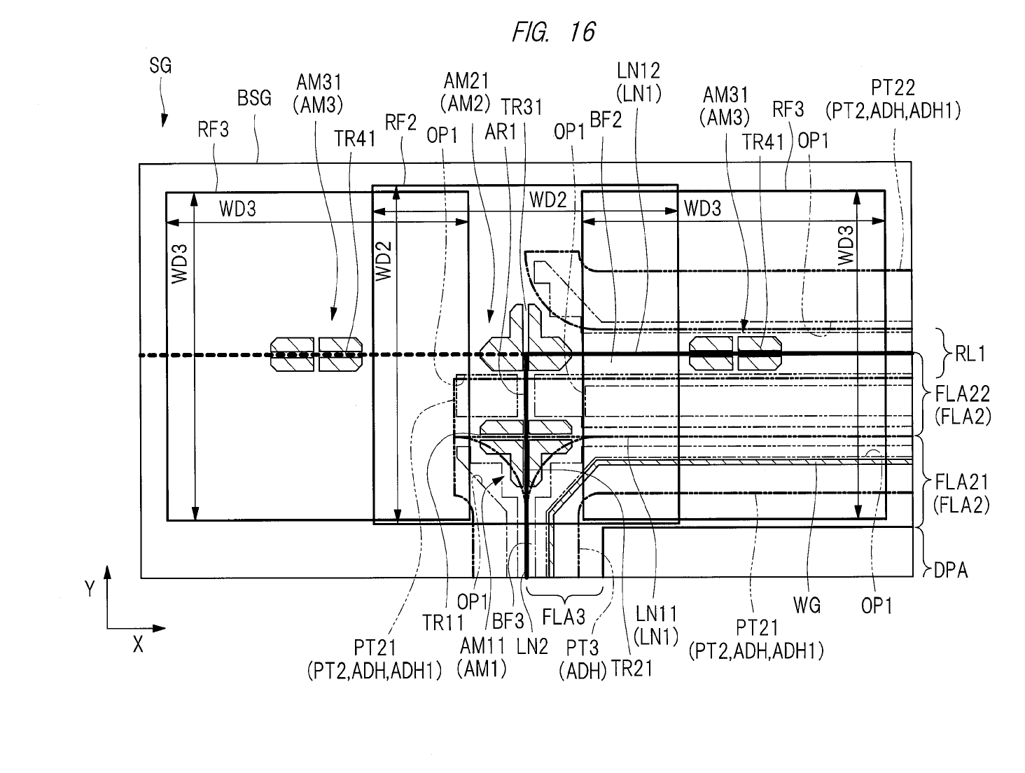

Note that it is possible to use various shapes other than the shapes illustrated in FIGS. 11 and 12 as each shape of the alignment marks AM1 and AM2 as long as it is possible to perform positioning with favorable shape accuracy through use of the alignment marks AM1 and AM2. In addition, the substrate assembly SG may include an alignment mark AM3 as will be described later with reference to FIGS. 15 and 16 in a modification example.

<Dummy Pattern>

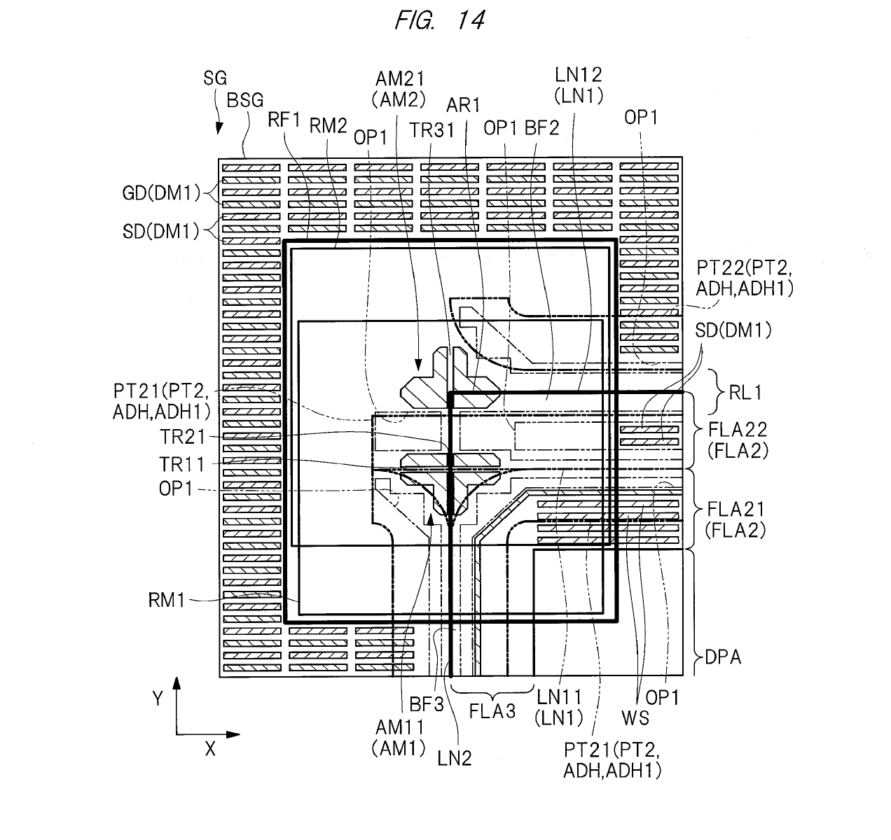

FIG. 14 is a plan view of the display device during the manufacturing process according to the embodiment. FIG. 14 illustrates a region illustrated in FIG. 11 and a region adjacent to the region illustrated in FIG. 11. In addition, FIG. 14 illustrates the alignment mark AM11 and the like formed on the counter surface BSf of the motherboard BSG.

Note that FIG. 14 illustrates a state seen through the interlayer resin film IL1 illustrated in FIG. 11. In addition, FIG. 13 corresponds to a cross-sectional view in a case where a dummy pattern DM1 is also formed near the alignment marks AM11 and AM21, that is, in a prohibited region RF1 to be described later. In addition, FIG. 14 illustrates a part of the wire WS.

As illustrated in FIG. 13 or 14, the substrate assembly SG includes a plurality of dummy patterns DM1 which are provided on the same layer as the plurality of scanning lines GL (see FIG. 4) or the plurality of signal lines SL (see FIG. 4). The plurality of dummy patterns DM1 include a plurality of dummy patterns GD and a plurality of dummy patterns SD. The plurality of dummy patterns GD are provided on the same layer as the plurality of scanning lines GL, and the plurality of dummy patterns SD are provided on the same layer as the plurality of signal lines SL. The plurality of dummy patterns GD and the plurality of dummy patterns SD may be provided inside the display panel formation region AR1 (see FIG. 13) or may be provided outside the display panel formation region AR1 as long as being provided outside the display region DPA.

The plurality of dummy patterns GD and the plurality of dummy patterns SD are configured to adjust an area ratio of patterns as will be described below. Accordingly, it is preferable that the plurality of dummy patterns GD and the plurality of dummy patterns SD be an electrically floating state.

When the alignment marks AM11 and AM21 are formed on the same layer as, for example, the plurality of scanning lines GL (see FIG. 4), an area ratio of patterns such as the plurality of scanning lines GL is large to a certain degree inside the display region DPA, but an area ratio of patterns formed on the same layer as the plurality of scanning lines GL is small outside the display region DPA. Accordingly, when a conductive film made of metal such as chromium (Cr) or molybdenum (Mo) or an alloy thereof is patterned by photolithography and etching to form the pattern on the same layer as the plurality of scanning lines GL, there is a risk that the shape accuracy of the pattern to be formed inside or outside the display region DPA deteriorates.

Meanwhile, as described above, the plurality of dummy patterns GD are provided outside the display region DPA, so that the area ratio of patterns formed on the same layer as the plurality of scanning lines GL outside the display region DPA can be made approximate to the area ratio of patterns such as the plurality of scanning lines GL formed inside the display region DPA. Accordingly, it is possible to improve both of the shape accuracy of the scanning line GL formed inside the display region DPA and the shape accuracy of the pattern formed on the same layer as the plurality of scanning lines GL outside the display region DPA.

Alternatively, when the alignment marks AM11 and AM21 are formed on the same layer as, for example, the plurality of signal lines SL (see FIG. 4), an area ratio of patterns such as the plurality of signal lines SL is large to a certain degree inside the display region DPA, but an area ratio of patterns formed on the same layer as the plurality of signal lines SL is small outside the display region DPA. Accordingly, when a conductive film made of a metal film having a multilayer structure in which, for example, aluminum (Al) is interposed between molybdenum (Mo) or the like is patterned by photolithography and etching to form the pattern on the same layer as the plurality of signal lines SL, there is a risk that the shape accuracy of the pattern to be formed inside or outside the display region DPA deteriorates.

Meanwhile, as described above, the plurality of dummy patterns SD are provided outside the display region DPA, so that the area ratio of patterns formed on the same layer as the plurality of signal lines SL outside the display region DPA can be made approximate to the area ratio of patterns such as the plurality of signal lines SL formed inside the display region DPA. Accordingly, it is possible to improve both of the shape accuracy of the signal line SL formed inside the display region DPA and the shape accuracy of the pattern formed on the same layer as the plurality of signal lines SL outside the display region DPA.

In this case, some of the dummy patterns GD among the plurality of dummy patterns GD or some of the dummy patterns SD among the plurality of dummy patterns SD may be formed on the substrate B.S. which is formed through the scribing process through use of the scribe line LN12. That is, the dummy pattern GD or the dummy pattern SD may be provided inside the frame region FLA (see FIG. 1) such as the frame region FLA2 inside the display panel formation region AR1.

For example, the dummy pattern GD or SD may be arranged inside the display panel formation region AR1 of the motherboard BSG, that is, inside the substrate B.S. and on the opposite side of the semiconductor chip CHP in the Y-axis direction with respect to the spacer SP21, that is, in the frame region FLA22 when seen in a plan view, as illustrated in the example of the dummy pattern SD in FIGS. 13 and 14. For example, when the motherboard BSG and the motherboard FSG are arranged to face each other, the dummy pattern GD or SD may be formed on the same layer as the scanning line GL or the signal line SL such that the dummy pattern GD or SD is arranged on the opposite side of the semiconductor chip CHP in the Y-axis direction with respect to the spacer SP21 when seen in a plan view. In this case, it is possible to improve both of the shape accuracy of the scanning line GL or the signal line SL formed inside the display region DPA and the shape accuracy of the dummy pattern GD or SD.

Note that the dummy pattern GD or SD may be arranged inside the substrate B.S. on the opposite side of the display region DPA with respect to the spacer SP21, when seen in a plan view, and the alignment marks AM11 and AM12 may be formed on the same layer as the plurality of scanning lines GL or the plurality of signal lines SL as described above. In this case, it is possible to improve any of the shape accuracy of the scanning line GL or the signal line SL formed inside the display region DPA, the shape accuracy of the dummy pattern GD or SD, and the shape accuracy of the alignment marks AM11 and AM12.

Preferably, the dummy patterns GD and SD are not arranged near the alignment marks AM11 and AM21 when seen in a plan view. Accordingly, misrecognition of the dummy patterns GD and SD as the alignment mark AM11 or AM21 can be prevented or suppressed when the vicinity of the alignment mark AM11 or AM21 is captured by a camera or the like provided in a scriber and a position where the scribing process is performed is determined based on a captured image, for example.

As illustrated in FIG. 14, it is preferable that the prohibited region RF1 in which the arrangement of the dummy patterns GD and SD is prohibited enclose a capturing range RM1 of the camera having the alignment mark AM11 as the center and a capturing range RM2 of the camera having the alignment mark AM21 as the center. In this case, the dummy patterns GD and SD are not arranged in the prohibited region RF1 in which the alignment marks AM11 and AM21 are enclosed but are arranged in a region outside the prohibited region RF1.

<Modification Example of Display Device>

The description has been given in the embodiment regarding the example in which the display device includes the alignment marks AM1 and AM2. Meanwhile, an example in which a display device includes the alignment mark AM3 in addition to the alignment marks AM1 and AM2 will be described as a modification example of the display device.

FIG. 15 is a plan view of a frame region of a display device according to the modification example of the embodiment. FIG. 15 illustrates an enlarged region RG3 of the display device illustrated in FIG. 5, which is surrounded by a two-dot chain line. In addition, FIG. 15 illustrates the alignment mark AM11 and the like formed on the substrate B.S. and the counter surface BSf of the substrate B.S. Note that FIG. 15 illustrates a state seen through the interlayer resin film IL1 illustrated in FIG. 6.

As illustrated in FIG. 15, the display device according to the modification example includes the alignment mark AM3. The alignment mark AM3 is provided in the end BF2 of the counter surface BSf of the substrate B.S. on the opposite side of the semiconductor chip CHP or the end FB2 (see FIG. 7) of the counter surface FSb of the substrate FS on the opposite side of the semiconductor chip CHP, although not illustrated in FIG. 15, and is arranged to be spaced apart from the alignment mark AM2. That is, the alignment mark AM3 is provided on the substrate B.S. or the substrate FS and is arranged at the same position as the alignment mark AM2 in the Y-axis direction. As illustrated in FIG. 15, the alignment mark AM3 formed in the substrate B.S. will be referred to as an alignment mark AM31.

The scribe line LN12 extending in the X-axis direction passes through the alignment mark AM2 and the alignment mark AM3 when seen in a plan view. Accordingly, it is possible to further improve the positional accuracy of the scribing process as will be described later with reference to FIG. 16.

Preferably, the alignment mark AM3 has a shape different from the shape of the alignment mark AM2. In this case, it is possible to easily improve the positional accuracy at the time of performing the scribing process along the scribe line LN12, as will be described later with reference to FIG. 16, by forming a trench portion TR41 extending in the X-axis direction, for example, in the alignment mark AM31.

Preferably, the alignment mark AM3 is not arranged near the alignment mark AM2 when seen in a plan view. Accordingly, misrecognition of the alignment mark AM3 as the alignment mark AM2 can be prevented or suppressed at the time of performing the scribing process, for example, as will be described later with reference to FIG. 16.

FIG. 16 is a plan view of the display device during a manufacturing process according to the modification example of the embodiment. FIG. 16 illustrates an enlarged region RG4 of the substrate assembly SG illustrated in FIG. 10, which is surrounded by a two-dot chain line. In addition, FIG. 16 illustrates the alignment mark AM11 and the like formed on the substrate B.S. and the counter surface BSf of the substrate B.S. Note that FIG. 16 illustrates a state seen through the interlayer resin film IL1 illustrated in FIG. 11.

As illustrated in FIG. 16, the alignment mark AM3 is formed on the substrate assembly SG in the present modification example. The alignment mark AM3 is provided in the end BF2 of the counter surface BSf of the display panel formation region AR1 of the motherboard BSG or the end FB2 (see FIG. 12) of the counter surface FSb of the display panel formation region AR2 of the motherboard FSG on the opposite side of the semiconductor chip CHP although not illustrated in FIG. 16. In addition, the alignment mark AM3 is arranged to be spaced apart from the alignment mark AM2. That is, the alignment mark AM3 is provided in the display panel formation region AR1 or the display panel formation region AR2 and is arranged at the same position as the alignment mark AM2 in the Y-axis direction. As illustrated in FIG. 16, the alignment mark AM3 formed on the motherboard BSG is referred to as the alignment mark AM31.

The scribe line LN12 extending in the X-axis direction passes through the alignment mark AM2 and the alignment mark AM3 when seen in a plan view. Accordingly, it is possible to perform the scribing process along the scribe line LN12 through use of the alignment marks AM2 and AM3 which are arranged to be spaced apart from each other in the X-axis direction, and thus, it is possible to further improve the positional accuracy of the scribing process as compared to the case of providing only the alignment mark AM2.

Preferably, the alignment mark AM3 has the shape different from the shape of the alignment mark AM2. In this case, it is possible to form the shape of the alignment mark AM3 to be similar to the shape of the alignment mark AM1 and to form the trench portion TR41 extending in the X-axis direction, for example, in the alignment mark AM31. In addition, it is possible to arrange the scribe line LN12 to pass through the trench portion TR41 when seen in a plan view.

The positioning accuracy in the Y-axis direction is improved in the case of using the alignment mark AM3 in which the trench portion TR41 extending in the X-axis direction is formed, as compared to the case of using the alignment mark AM2 in which the trench portion extending in the X-axis direction is not formed. Accordingly, it is possible to easily improve the positional accuracy at the time of performing the scribing process along the scribe line LN12 by forming the trench portion TR41 in the alignment mark AM3.

Note that the alignment mark AM3 may be arranged outside the display panel formation region AR1 or outside the display panel formation region AR2 as long as it is possible to perform the scribing process through use of the alignment mark AM3. Accordingly, the alignment mark AM3 may not be necessarily provided in the end BF2 of the counter surface BSf of the display panel formation region AR1 on the opposite side of the semiconductor chip CHP or may not be necessarily provided in the end FB2 (see FIG. 12) of the counter surface FSb of the display panel formation region AR2 of the motherboard FSG on the opposite side of the semiconductor chip CHP. As illustrated in FIG. 16, the alignment mark AM3 may be arranged outside the display panel formation region AR1 or outside the display panel formation region AR2 and arranged at the same position as the alignment mark AM2 in the Y-axis direction.

Preferably, the alignment mark AM3 is not arranged near the alignment mark AM2 when seen in a plan view, and the alignment mark AM2 is not arranged near the alignment mark AM3 when seen in a plan view.

Accordingly, misrecognition of the alignment mark AM3 as the alignment mark AM2 can be prevented or suppressed when the vicinity of the alignment mark AM2 is captured by the camera or the like provided in the scriber and a position to perform the scribing process is determined based on a captured image, for example. In addition, misrecognition of the alignment mark AM2 as the alignment mark AM3 can be prevented or suppressed when the vicinity of the alignment mark AM3 is captured by the camera or the like provided in the scriber and a position to perform the scribing process is determined based on a captured image, for example.

Note that, in this case, misrecognition of the alignment mark AM3 as the alignment mark AM1 as well as misrecognition of the alignment mark AM1 as the alignment mark AM3 can also be prevented or suppressed.

As illustrated in FIG. 16, the alignment mark AM3 is not arranged in the region RF2 which has a center of the alignment mark AM2 as the center and encloses the alignment mark AM2 but is arranged in a region outside the region RF2. Meanwhile, the alignment mark AM2 is not arranged in the region RF3 which has the center of the alignment mark AM3 as the center and encloses the alignment mark AM3 but is arranged in a region outside the region RF3. It is possible to set each width WD2 of the region RF2 in the X-axis direction and the Y-axis direction and each width WD3 of the region RF3 in the X-axis direction and the Y-axis direction to about 2 mm, for example.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, the present invention can be also applied to a case where it is possible to manufacture three or more types of display devices having different widths of upper frame regions through use of one type of photomask as another application example thereof, although the case where it is possible to manufacture two types of display devices having different widths of upper frame regions through use of one type of photomask has been exemplified in the embodiment as a disclosed example. In addition, each of the substrates has a quadrangular (rectangular) shape in the embodiment but maybe a polygonal shape, a circular shape, an elliptical shape, or a polygonal shape having some arc sides. For example, it is possible to form a circular panel and a circular panel a part of which is a straight line through use of one type of photomask according to the invention of the present application.

In addition, although the liquid crystal display device has been exemplified as the disclosed example in the embodiment, as other application examples of the present invention, examples include all flat-panel display devices such as an organic EL display device, other self-luminous display device, and an electronic paper display device including an electrophoretic element or the like. In addition, it is needless to say that the invention can be applied to display devices having a small size to a large size without being particularly limited.

Various modifications and alterations can be conceived by those skilled in the art within the spirit of the present invention, and it is understood that such modifications and alterations are also encompassed within the scope of the present invention.

For example, those skilled in the art can suitably modify the above-described embodiment by addition, deletion, or design change of components, or by addition, omission, or condition change of steps. Such modifications are also encompassed within the scope of the present invention as long as they include the gist of the present invention.

The present invention is advantageous when being applied to a display device.

What is claimed is:

1. A display device comprising:
a first substrate;
a second substrate arranged to face the first substrate; and
a seal provided between the first substrate and the second substrate and allowing the first substrate and the second substrate to adhere to each other,
wherein the first substrate includes
a first region, and
a second region which is arranged on a first side in a first direction with respect to the first region when seen in a plan view,
a plurality of pixels are arranged in the first region,
the seal is provided in a first part and a second part in the second region when seen in a plan view,
the first part is arranged on the first region side with respect to a spacer,
the second part is arranged on an opposite side of the first region with the spacer interposed therebetween, and
the spacer is formed from a first end to a second end of the second substrate at a boundary between the first part and the second part, and the spacer is in contact with the seal on the first part side and the second part side of the spacer.

2. The display device according to claim 1, comprising:
a first alignment mark provided in the first substrate or the second substrate,
wherein the first alignment mark is superimposed on the spacer in the first direction.

3. The display device according to claim 2,
wherein the first alignment mark is provided in the first part at the boundary between the first part and the second part, and
a second alignment mark is provided in a third end of the first substrate or the second substrate in the second part.

4. The display device according to claim 1, comprising:
a plurality of scanning lines and a plurality of signal lines provided in the first substrate,
wherein a pattern provided on a same layer as the plurality of scanning lines or the plurality of signal lines is arranged in the second part when seen in a plan view, and
the pattern is floating.

5. The display device according to claim 1,
wherein a third end of the first substrate and a fourth end of the second substrate in the second part are exposed from the seal.

6. The display device according to claim 3,
wherein the second alignment mark has a shape different from a shape of the first alignment mark when seen in a plan view.

7. The display device according to claim 1,
wherein the spacer is a plurality of island-like spacers interspersed in an extension direction of a plurality of scanning lines.

8. A method of manufacturing a display device, the method comprising the steps of:
(a) providing a plurality of pixels, respectively, in a plurality of substrate formation regions of a first motherboard;
(b) providing a spacer, a first alignment mark, and a second alignment mark, respectively, in a plurality of substrate formation regions of a second motherboard;
(c) bonding the first motherboard and the second motherboard to each other via a seal;
(d) determining whether the substrate formation region is scribed by a first size or a second size larger than the first size; and
(e) dividing the first motherboard and the second motherboard into a plurality of display panels through the scribing.

9. The method of manufacturing the display device according to claim 8,
wherein vicinity of the first alignment mark is cut inscribing by the first size, and
vicinity of the second alignment mark spaced apart from the plurality of pixels farther than the first alignment mark is cut in scribing by the second size.

10. The method of manufacturing the display device according to claim 8,
wherein the scribing is performed along the spacer in scribing by the first size.
